(19) United States
(12) Patent Application Publication
(10) Pub. No.: US 2025/0280613 A1
(43) Pub. Date: Sep. 4, 2025

(54) IMAGE SENSOR WITH PHASE DETECTION AUTOFOCUS PIXEL

(71) Applicant: OMNIVISION TECHNOLOGIES, INC., Santa Clara, CA (US)

(72) Inventors: Yen-Yun Wang, San Jose, CA (US); Chen-Wei Lu, San Jose, CA (US); Dyson Hsin-Chih Tai, San Jose, CA (US); Chao Niu, Santa Clara, CA (US)

(21) Appl. No.: 18/984,519

(22) Filed: Dec. 17, 2024

Related U.S. Application Data
(60) Provisional application No. 63/560,375, filed on Mar. 1, 2024.

(51) Int. Cl. H10F 39/00; H10F 39/18

(52) U.S. Cl. CPC H10F 39/8023; H10F 39/182; H10F 39/805; H10F 39/8057; H10F 39/8063

(57) ABSTRACT

A phase detection autofocus (PDAF) pixel cell and an image sensor including a PDAF pixel cell is described. The PDAF pixel cell includes a photosensitive region including one or more photodiodes formed within a semiconductor material proximate to a backside surface of the semiconductor material, a microlens optically aligned with the photosensitive region; and a spectral filter disposed between the microlens and the metal shield. A first lateral width of the spectral filter is less than a second lateral width of the metal shield along a direction parallel to the backside surface to form a gap extending from an edge of the spectral filter toward an edge of the metal shield when viewed from a plan view.

### CROSS-REFERENCE TO RELATED APPLICATION

This application claims the benefit of U.S. Provisional Application No. 63/560,375, filed Mar. 1, 2024, which is hereby incorporated by reference in its entirety.

### TECHNICAL FIELD

This disclosure relates generally to image sensors, and in particular but not exclusively, relates to phase detection autofocus (PDAF) pixels for image sensors.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing. However, it is appreciated that many of these metrics are inversely related. For example, pixel size may be increased to improve dynamic range but have increased noise. In another example, resolution may be increased by increasing the number of pixels, but if pixel size is maintained then the physical size of the image sensor increases. Accordingly, improving one or more performance metrics of semiconductor devices such as image sensors while mitigating adverse effects on other performance metrics remains challenging.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to produce digital images (i.e., image data) representative of the external scene.

In some imaging applications, image sensors may employ a technique known as phase detection autofocus (PDAF) to perform autofocus by measuring an offset or phase difference between two image signals of the same object or external scene generated from different perspectives. The two image signals may be used to determine a relative position between an object of interest and a focal plane of the image sensor. The computed magnitude and sign of the calculated phase difference may be correlated to an amount of defocus that can be used to estimate an amount of lens displacement needed to have the image in focus.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1 illustrates an example pixel array that includes a plurality of quad phase detection (QPD) pixel cells, in accordance with teachings of the disclosure.

FIG. 2A illustrates an example layout showing a partial pixel cell array for an image sensor featuring a dedicated phase detection autofocus (PDAF) pixel cell, in accordance with teachings of the disclosure.

FIG. 2B illustrates a cross-sectional view of the partial pixel cell array illustrated in FIG. 2A along cutline A-A′, in accordance with teachings of the disclosure.

FIG. 3 illustrates a cross-sectional view and a plan view of a partial pixel cell array of an image sensor including a PDAF pixel cell with reduced induced crosstalk, in accordance with teachings of the disclosure.

FIG. 4A illustrates an exemplary partition of a pixel cell array that includes a plurality of PDAF pixel cells into regions of interests (ROI), in accordance with teachings of the disclosure.

FIG. 4B illustrates a first pair of PDAF pixel cells including a left-oriented PDAF pixel cell and a right-oriented PDAF pixel cell located within any of ROI 1, ROI 2, or ROI 3 illustrated in FIG. 4A, in accordance with teachings of the disclosure.

FIG. 4C illustrates a second pair of PDAF pixel cells including a left-oriented PDAF pixel cell and a right-oriented PDAF pixel cell located within any of ROI 4, ROI 5, or ROI 6 illustrated in FIG. 4A, in accordance with teachings of the disclosure.

FIG. 4D illustrates a third pair of PDAF pixel cells including a left-oriented PDAF pixel cell and a right-oriented PDAF pixel cell located within any of ROI 7, ROI 8, or ROI 9 illustrated in FIG. 4A, in accordance with teachings of the disclosure.

FIG. 4E illustrates a more detailed view of left and right oriented PDAF pixel cells illustrated in FIG. 4B-4E, in accordance with teachings of the disclosure.

FIG. 5 illustrates a cross-sectional view and a plan view of a partial pixel cell array of an image sensor including a PDAF pixel cell with reduced induced crosstalk, in accordance with teachings of the disclosure.

FIG. 6 illustrates left and right oriented PDAF pixel cells with two spectral filters disposed over corresponding metal shields, in accordance with teachings of the disclosure.

FIG. 7 illustrates a cross-sectional view and a plan view of a partial pixel cell array of an image sensor including a PDAF pixel cell with a combination of a spectral filter and an antireflection layer for reduced induced crosstalk, in accordance with teachings of the disclosure.

FIG. 8 illustrates a block diagram of an imaging system for an image sensor, in accordance with teachings of the disclosure.

### DETAILED DESCRIPTION

Embodiments of an apparatus, system, and method each related to an image sensor with a phase detection autofocus (PDAF) pixel are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

Further still, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The term “have”, “may have”, “include”, “may include” or “comprise” used herein indicates the existence of a corresponding feature (e.g., a number, a function, an operation, or an element) and does not exclude the existence of an additional feature.

The term “A or B”, “at least one of A and/or B”, or “one or more of A and/or B” may include all possible combinations of items listed together. For example, the term “A or B”, “at least one of A and B”, or “at least one of A or B” may indicate all the cases of (1) including at least one A, (2) including at least one B, and (3) including at least one A and at least one B.

It will be understood that when a certain element (e.g., a first element) is referred to as being “operatively or communicatively coupled with/to” or “connected to” another element (e.g., a second element), the certain element may be coupled to the other element directly or via another element (e.g., a third element). However, when a certain element (e.g., a first element) is referred to as being “directly coupled” or “directly connected” to another element (e.g., a second element), there may be no intervening element (e.g., a third element) between the element and the other element.

The term “configured (or set) to” may be interchangeably used with the term, for example, “suitable for”, “having the capacity to”, “designed to”, “adapted to”, “made to”, or “capable of”. The term “configured (or set) to” may not necessarily have the meaning of “specifically designed to”. In some cases, the term “device configured to” may indicate that the device “may perform” together with other devices or components. For example, the term “processor configured (or set) to perform A, B, and C” may represent a dedicated processor (e.g., an embedded processor) for performing a corresponding operation, or a generic-purpose processor (e.g., a CPU or an application processor) for executing at least one item of software or program stored in a memory device to perform a corresponding operation.

The term “vertical” refers to a direction that is perpendicular to a surface of a substrate or material layer.

The term “high-K material” herein refers to a material having a dielectric constant that is greater than 3.9. In some embodiments, term “high-K material” may also refer to a material having a dielectric constant that is greater than a dielectric constant of the silicon dioxide (SiO2).

The term “p-type” defines a structure, layer, and/or region in a substrate material layer (e.g., semiconductor substrate or epitaxial layer) as being doped with p-type dopant, such as boron.

The term “n-type” defines a structure, layer, and/or region in a substrate material layer (e.g., semiconductor substrate or epitaxial layer) as being doped with n-type dopant, such as phosphorus and/or arsenic.

In some embodiments, the term “about” and the term “substantially” can refer to a value of a given quantity or manufacturing parameters that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings of the disclosure.

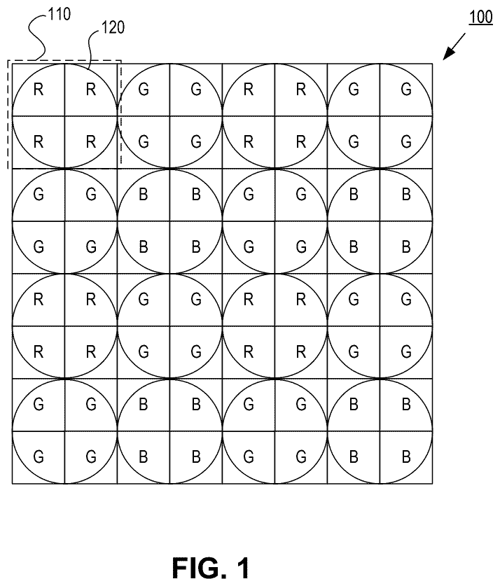

FIG. 1 illustrates an example pixel array 100 that includes a plurality of quad phase detection (QPD) pixel cells 110, in accordance with teachings of the disclosure. As illustrated in FIG. 1, QPD pixel cells 110 are arranged in accordance to a Bayer pattern with each QPD pixel cell including four pixels (e.g., photodiodes) that share a same color filter (e.g., “R” for red color filters, “G” for green filters, and “B” for blue color filters) and further share a same microlens included in plurality of microlenses 120. Advantageously, plurality of QPD pixel cells 110 may be used for both imaging and autofocus when each individual pixel included in plurality of QPD pixel cells 110 are being read out. Specifically, a single microlens optically aligned with a group of photodiodes as illustrated in FIG. 1 enables images signals of different perspectives to be captured (e.g., to employ phase difference autofocus techniques by comparing, for example, image signals generated with left pixels to image signals generated with right pixels).

An image sensor with plurality of QPD pixel cells 110 may be operated in a high resolution mode (e.g., a “1C” mode) or a binning mode (e.g. a “4C” mode). When operating in the high resolution mode, each individual photodiode or pixel included in plurality QPD pixel cells 110 is readout to achieve high resolution. When operating in the binning mode, multiple photodiodes of a given pixel cell included in plurality of QPD pixel cells 110 are binned together for readout. For example, during the 4C mode (e.g., 2-by-2 binning mode), four photodiodes (e.g., four photodiodes of a given pixel cell included in plurality of QPD pixel cells 110) of a same color are binned together for readout. Modes of operation may be selected based on target pixel performance (e.g., 1C mode offers lower noise performance relative to 4C mode while 4C mode offers faster readout relative to 1C mode).

However, autofocus remains limited when operating plurality of QPD pixel cells 110 in 4C mode since, for example, there is a lack of an aperture to split light for generating phase difference images (e.g., each photodiode included in a given pixel cell is binned for readout meaning plurality of QPD pixel cells 110 may not be able to form left and right images for phase detection). In other words, phase detection autofocus may not be readily employed using plurality of QPD pixel cells 110 operating in 4C mode. Embodiments of the disclosure included dedicated phase detection pixel cells compatible with, but not necessarily exclusively for, image sensors operating in a binning mode (e.g., 4C mode).

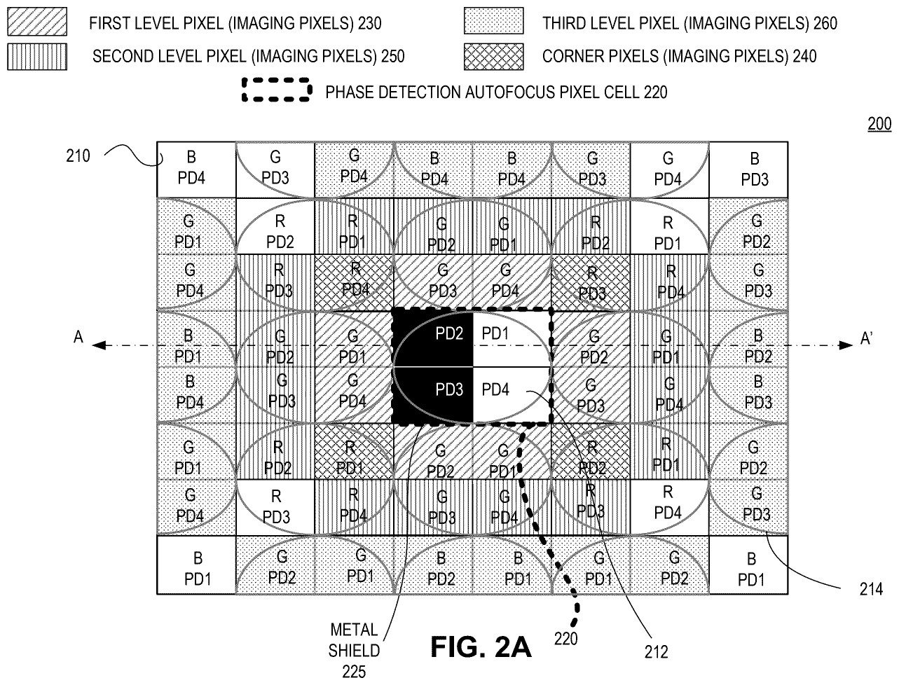

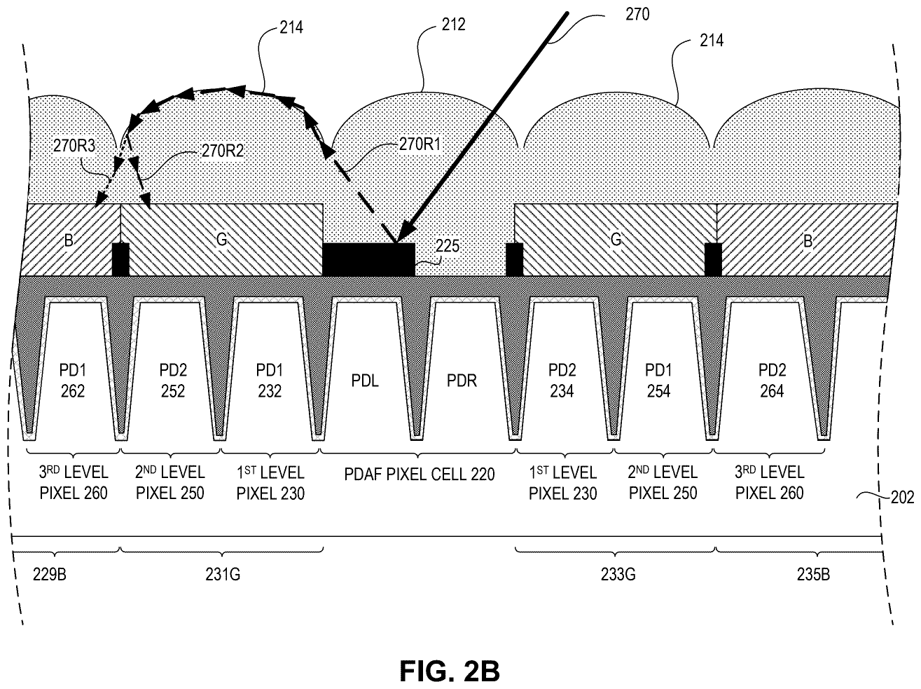

FIG. 2A illustrates an example layout showing a partial pixel cell array for an image sensor featuring a dedicated phase detection autofocus (PDAF) pixel cell, in accordance with teachings of the disclosure. As illustrated, pixel cell array 200 includes a plurality of QPD pixel cells 210 arranged in rows and columns in a Bayer pattern. Plurality of QPD pixel cells 210 generates electrical or image signals in response to incident light (e.g., light 270 illustrated in FIG. 2B). Individual pixel cells included in plurality of QPD pixel cells 210 each include four photodiodes (i.e., PD1-PD4) of a same color (e.g., “R”, “G”, or “B”, which respectively correspond to red, green, or blue pixels) under a single or same microlens 214. It is appreciated that in some embodiments plurality of QPD pixels 210 may be arranged based on non-Bayer pattern such as red, green, blue and infrared, or red, green, blue, and clear, etc.). Microlens 214 may be configured with an appropriate size to cover or otherwise be optically aligned with the photosensitive region of a respective pixel cell (e.g., an individual microlens of a given pixel cell is optically aligned with or otherwise disposed over all photodiodes included in the given pixel cell for each pixel cell included in plurality of QPD pixel cells 210). In some embodiments, individual pixel cells of plurality of QPD pixel cells 210 are referred to as imaging pixel cells. However, it is appreciated that the imaging pixel cells may be also used for phase detection autofocus when operating in high resolution mode.

To enable autofocus when operating in binning mode (e.g., 4C mode), pixel cell array 200 includes sparsely distributed phase detection autofocus pixel cells 220 dedicated to phase detection. As illustrated, PDAF pixel cells 220 corresponds to QPD pixel cells with a clear or omitted color filter having half of the pixels (e.g., a subgroup of two photodiodes on the left or right side) shielded (e.g., via metal or opaque shield 220) to create an asymmetry to generate left or right images (e.g., left and right oriented metal shields may be used to form left and right oriented PDAF pixel cells 220 that may be respectively used to generate left and right image signals that may be compared for phase detection).

However, it has been found that PDAF pixel cells 220 may lead to crosstalk affecting sensitivity of neighboring normal color imaging pixels (i.e., plurality of QPD pixel cells 210 including first level pixel 230, second level pixel 250, third level pixel 260, and/or corner pixel 240). It has been observed that metal shield 220 used to block light for PDAF pixel cells 220 result in notable levels of optical crosstalk to proximate pixel cells included in plurality of QPD pixel cells 210 due to reflection and/or refraction. Such crosstalk may be referred to as phase detection (PD) crosstalk. PD crosstalk herein may be defined as the sensitivity impact that a metal shield based phase detection pixel (i.e., PDAF pixel cells 220) has on surrounding or nearby imaging pixel cells (e.g., first level pixel 230, second level pixel 250, third level pixel 260, and/or corner pixel 240).

FIG. 2B illustrates a cross-sectional view of the partial pixel cell array 200 illustrated in FIG. 2A along cutline A-A′, in accordance with teachings of the disclosure. PDAF pixel cell 220 includes four photodiodes (e.g., a first photodiode PD1, a second photodiode PD2, a third photodiode PD3, and a fourth photodiode PD4) arranged in a two-by-two array to form left photodiodes PDL and right photodiodes PDR formed in semiconductor material 202. A microlens 212 is optically aligned with left photodiodes PDL and right photodiodes PDR to direct incident light towards left photodiodes PDL and right photodiodes PDR. PDAF pixel cell 220 may be referred to as a half-shield phase detection autofocus pixel cell since metal shield 225 (e.g., formed of a metal material to create an opaque layer that includes a metal material such as aluminum or tungsten) covers half of the photodiodes (e.g., left photodiodes corresponding to PDL) included in PDAF pixel cell 220 while leaving the remaining photodiodes of PDAF pixel cell 220 uncovered (e.g., right photodiodes corresponding to PDR). In the illustrated embodiment, metal shield 225 is disposed between the microlens 212 and left photodiodes PDL to block incident light from entering the left half of a photosensitive region (e.g., corresponding to left photodiodes PDL and right photodiodes PDF, collectively) of PDAF pixel cell 220. It is appreciated that the orientation of metal shield 225 may be flipped (e.g., to cover right photodiodes PDR while leaving left photodiodes PDL uncovered) such that left and right image signals may be generated and compared for phase detection autofocus. In other words, left-shielded PDAF pixel cells and right-shielded PDAF pixel cells may be used in combination for phase detection autofocus to determine how much displacement of a lens is necessary to focus on a particular point of interest.

However, it has been found that metal shield 225 for PDAF pixel cell 220 may cause optical crosstalk to surrounding imaging pixels (e.g., plurality of QPD pixel cells 210) that are positioned in proximity to PDAF pixel cell 220 (e.g., first level pixels 230, second level pixels 250, third level pixels 260, and/or corner pixels 240) due, for example, to reflection and/or refraction associated with PDAF pixel cell 220. Such crosstalk may be referred to as phase detection (PD) crosstalk. PD crosstalk herein may be defined as the sensitivity impact that PDAF pixel cells 220 has on surrounding or nearby imaging pixels included in plurality of QPD pixel cells 220 (e.g., relative to pixels included in plurality of QPD pixel cells 220 that are farther away and unaffected by PDAF pixel cells 220). For example, pixel cell 229B (e.g., including photodiode PD1 262), pixel cell 231G (e.g., including photodiodes PD1 232 and PD2 252), pixel cell 233G (e.g., including photodiodes PD1 254 and PD2 234), and pixel cell 235B (e.g., including photodiode PD2 264) may each have elevated crosstalk levels due, at least in part, to PDAF pixel cell 220.

In one example, incident light ray 270 may reflect off metal shield 225 to form reflected light ray 270R1 that follows a curvature of microlens 214 associated with an adjacent pixel cell included in plurality of QPD pixel cells 210 (e.g., pixel cell 231G) and may result in multiple reflected light rays (e.g., rays 270R2 and 270R3) directed towards the photosensitive regions of nearby pixels (e.g., photodiode PD2 252 and/or photodiode PD1 262) In other words, light incident on metal shield 225 included in PDAF pixel cell 220 may be reflected, scattered, diffracted and subsequently sensed by photodiodes included in neighboring pixel cells included in QPD pixel cells 210. For example, it has been found that first level pixels 230 that are immediately adjacent to PDAF pixel cell 220 (e.g., directly adjacent to PDAF pixel cell 220 along a same column or same row) may have at least a 5% signal crosstalk level, second level pixels 250 (e.g., pixels directly adjacent to first level pixels 230) and/or corner pixels 240 (e.g., diagonally adjacent to PDAF pixel cell 220) may have at least a 2% signal crosstalk level, and/or third pixel cells 260 (e.g., directly adjacent to second level pixels 250) may have at least a 1% signal crosstalk level associated with PDAF pixel cell 220. It is appreciated that the aforementioned signal crosstalk levels associated with PD crosstalk correspond to the amount of deviation in crosstalk relative to other QPD pixel cells included in plurality of QPD pixel cells 210 that are not influenced by PDAF pixel cell 220. Embodiments of the disclosure provide an improved PDAF pixel cell relative to PDAF pixel cell 220 that mitigates the issue of PD crosstalk while also being compatible with binning modes of operation.

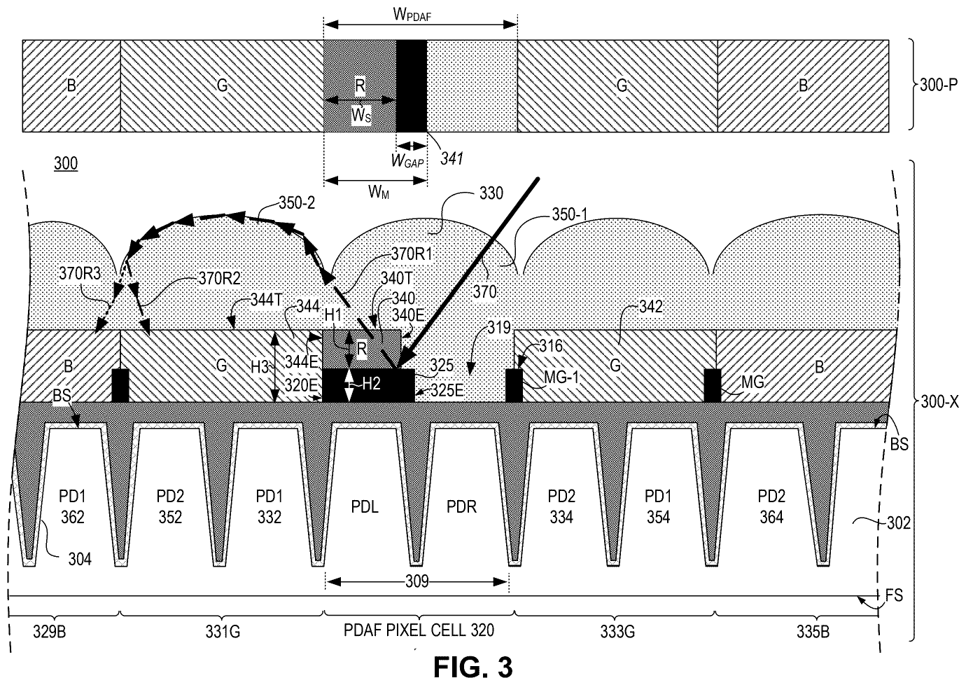

FIG. 3 illustrates a cross-sectional view 300-X and a plan view 300-P of a partial pixel cell array of an image sensor including a PDAF pixel cell 320 with reduced induced crosstalk, in accordance with teachings of the disclosure. PDAF pixel cell 320 represents an improved phase detection structure relative to PDAF pixel cell 220 illustrated in FIG. 2A-2B. In the illustrated embodiment, PDAF pixel cell 320 includes a plurality of photodiodes, including left photodiodes PDL and right photodiodes PDR (e.g., first, second, third, and forth photodiodes arranged in a two-by-two array) surrounded by imaging pixels (e.g., pixel cell 329B including photodiode PD1 362, pixel cell 331G including photodiode PD2 352 and PD1 332, pixel cell 333G including photodiode PD2 334 and PD1 354, and pixel cell 335B including photodiode 364) formed within semiconductor material 302. PDAF pixel cell 320 further includes metal shield 325, spectral filter 340, and microlens 350-1.

PDAF pixel cell 320 includes a photosensitive region 309 (e.g., defined by isolation structure 304) formed in semiconductor material 302 corresponding to regions where left photodiodes PDL and right photodiodes PDR are located (e.g., doped regions of semiconductor material 302 that collectively form left photodiodes PDL and right photodiodes PDR). In other words, PDAF pixel cell 320 includes photosensitive region 309 including one or more photodiodes (e.g., left photodiodes PDL and right photodiodes PDR) formed within semiconductor material 302 proximate to a backside surface BS of semiconductor material 302. Semiconductor material 302 includes front side surface FS and the backside surface BS opposite of the front side FS. It is appreciated, backside surface BS may sometimes be referred to as an illuminated side and front side surface FS may be referred to as a non-illuminated side. As illustrated, microlens 350-1 is optically aligned with photosensitive region 309 (e.g., to direct light towards left photodiodes PDL and right photodiodes PDR). Metal shield 325 is disposed between microlens 350-1 and photosensitive region 309 (e.g., to block incident light from reaching left photodiodes PDL or right photodiodes PDR depending on an orientation of PDAF pixel cell 320).

In illustrated embodiment, PDAF pixel cell 320 may be laterally surrounded by a plurality of QPD pixel cells (e.g., pixel cells 329B, 331G, 333G, 335B) and may be dedicated for phase detection. In other words, PDAF pixel cell 320 may provide phase detection for the plurality of QPD pixel cells operating in binning mode. Photodiodes included in plurality of QPD pixel cells and PDAF pixel cell 320 correspond to doped regions disposed or formed within semiconductor material 302. In some embodiments, semiconductor material 302 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, semiconductor material 302 may correspond to any semiconductor material or combination of materials that may be doped or otherwise configured to facilitate the formation of an integrated circuit (e.g., individual circuitry components such as source/drain regions of transistors, memory elements, photodiodes, or the like). In one embodiment, semiconductor material 302 corresponds to an epitaxial layer (e.g., P-type silicon layer or N-type silicon layer). In such an embodiment, photodiodes (e.g., left photodiodes PDL, right photodiode PDR, or other photodiodes annotated through the disclosure as PD1, PD2, PD3, or PD4) throughout the disclosure may be formed in the epitaxial layer corresponding to semiconductor material 302.

It is appreciated that the term “photodiode” (e.g., left photodiodes PDL, right photodiode PDR, or other photodiodes annotated through the disclosure as PD1, PD2, PD3, or PD4) correspond to a doped region (e.g., formed via implantation) disposed within or otherwise surrounded by an oppositely doped region to form a photosensitive area capable of photogenerating image charge in response to incident light. For example, individual photodiodes included in left photodiodes PDL and/or right photodiodes PDR may correspond to an N-type semiconductor region (e.g., N-doped silicon region) disposed within a P-type semiconductor material (e.g., P-type doped silicon corresponding to semiconductor material 302). Accordingly, in some embodiments individual photodiodes included in PDAF pixel cell 320 illustrated in FIG. 3 or other photodiodes throughout the disclosure each include a doped region that is oppositely doped (e.g., opposite conductivity type) relative to a doping type of semiconductor material 302 to form a PN junction for photo-sensing operation.

In the illustrated embodiment, pixel cell array 300 includes isolation structure 304 (e.g., a plurality of deep trench isolation structures) formed in semiconductors material 302 to provide isolation between individual photodiodes (e.g., left photodiodes PDL and right photodiodes PDR may be isolation from each other via isolation structure 304) included in phase detection autofocus pixel cells and normal imaging pixel cells (e.g., pixel cells 329B, 331G, 333G, 335G, and so on). In some embodiments, isolation structure 304 may be arranged to form a grid defining photosensitive areas of individual photodiodes and/or pixel cells. As illustrated, isolation structure extends from a backside surface BS of semiconductor material 302 toward front side surface FS of semiconductor material 302. In some embodiments, the left photodiodes PDL and right photodiodes PDR may be further isolated from each other by a junction isolation structure (not illustrated) or a combination of deep trench isolation structures included in isolation structure 304 and a junction isolation structure. In an embodiment, the junction isolation structure may be implemented by ion implantation of one or more dopant types (e.g., via P-type dopants such as boron) having an opposite conductivity type to the doped regions that form photodiodes included in pixel cell array 300 (e.g., via N-type dopants such as phosphorus or arsenic).

In some embodiments, a metal grid 316 is formed between individual color filters (“R”, “G”, or “B”) of the color filter array. In the same or other embodiments, metal grid 316 may be vertically aligned with isolation structure 304 to form a plurality of apertures defining light exposure or sensing regions of individual pixels or pixel cells included in pixel cell array 300. Apertures formed by metal grid 316 may be filled with individual color filters such that a given pixel or pixel cell is associated with a predetermined color (e.g., red, green, or blue). Metal grid 316 includes a plurality metal grid segments MG separating each individual color filter.

PDAF pixel cell 320 includes microlens 350-1 optically aligned with photosensitive region 309 to cover left photodiodes PDL and right photodiodes PDR. Metal shield 325 partially covers photosensitive region 309 and is further disposed between microlens 350-1 and left photodiodes PDL to block incident light (e.g., light 370) from reaching left photodiodes PDL. However, it is appreciated that metal shield 325 may be arranged in a different orientation over right photodiodes PDR to block incident light from reaching right photodiodes PDR (e.g., such that two differently oriented PDAF pixel cells may be utilized to form left and right images for phase detection autofocus). Metal shield 325 has a lateral width W_{M} that is less than lateral width W_{PDAF} of PDAF pixel cell 320. In the illustrated embodiment, microlens 350-1 is arranged to cover all or part of a light exposure region of PDAF pixel cell 320 depending on a position of PDAF pixel cell 320 within pixel cell array 300. In some embodiments, metal shield 325 is formed at the same time as metal grid 316. Metal grid 316 includes a plurality of metal grid segments MG, MG-1 disposed between individual color filters (e.g., green color filter “G”, blue color filter “B”, red color filter “R”).

PDAF pixel cell 320 further includes a spectral filter 340 (e.g., a red color filter) disposed between microlens 350-1 and metal shield 325. In some embodiments, spectral filter 340 has a photoresponse different from the photoresponse of color filters laterally surrounding PDFAF pixel cell 320 (e.g., spectral filter 340 of PDAF pixel cell 320 corresponds to a red color filter as illustrated that is laterally surrounded by green or blue color filters). Put in another way, a first photoresponse of spectral filter 340 (e.g., a red color filter) included in PDAF pixel cell 320 is different than a second photoresponse of corresponding spectral filters including in imaging pixel cells (e.g., blue color filter or green color filter) laterally surrounding PDAF pixel cell 320 (e.g., imaging pixel cells 329B, 331G, 333G, 335B, etc.). Spectral filter 340 reduces crosstalk attributed to PDAF pixel cell 320 by reducing light reflecting from metal shield 325 and further attenuating light that adjacent color filters transmit. For example, incident light 370 may reflect off metal shield 325 to form reflected rays 370R1, 370R2, and/or 370R3. However, spectral filter 340 filters or attenuates incident light 370 and/or reflected ray 370R1 that is outside of the red range (e.g., red light having a wavelength range between 600 nm and 750 nm is transmitted while other visible or non-visible light outside of the 600 nm to 750 nm range is attenuated). Consequently, reflected ray 370R1, 370R2, and 370R3 comprise primarily red light that is subsequently filtered or otherwise attenuated by the color filters of adjacent imaging pixel cells (e.g., blue or green color filters included in imaging pixel cells 329B, 331G, 333G, and/or 335B attenuate the primarily red light of reflected rays 370R1, 370R2, and 370R3 to reduce PD crosstalk).

To avoid lowering the selectivity of PDAF pixel cell 320, spectral filter 340 does not fully cover metal shield 325. Additionally, to increase quantum efficiency, no spectral filter is disposed over an uncovered portion of photosensitive region 309 defined by metal shield 325 (i.e., the partial coverage of photosensitive region 309 provided by metal shield 325 defines an uncovered portion of photosensitive region 309). Thus, in some embodiments, spectral filter 340 does not extend over the uncovered portion of the photosensitive region 309. Additionally, spectral filter 340 partially covers metal shield 325 to define an uncovered portion (e.g., corresponding to gap 341) of metal shield 325. Put in another way, spectral filter 340 partially covers metal shield 325 and metal shield 325 partially covers photosensitive region 309. As illustrated, a first lateral width W_{S} of spectral filter 340 is less than a second lateral width W_{M} of metal shield 325 along a direction parallel to the backside surface BS to form gap 341 (e.g., corresponding to a portion of metal shield 325 that is not covered by spectral filter 340) extending toward an edge 325E of metal shield 325 when viewed from a plan view (e.g., as shown by plan view 300-P illustrated in FIG. 3). In the illustrated embodiment, a third lateral width W_{GAP} of the gap 341 along the direction parallel to the backside surface BS is less than the first lateral width W_{S} of spectral filter 340. In some embodiments, gap 341 is filled by a transparent microlens material 330 included in microlens 350-1. In the same or other embodiments, microlens material 330 fills a gap 319 defined by metal shield 325 such that microlens material 330 is disposed between metal shield 325 (e.g., edge 325E) and a proximal metal grid segment MG-1 included in metal grid 316. In an embodiment, edge 325E of metal shield 325 corresponds to an inner edge of metal shield 325 disposed closer to a midpoint of photosensitive region 309 (e.g., a lateral point disposed between left photodiodes PDL and right photodiodes PDR) relative to an outer edge (e.g., edge of metal shield 325 that interfaces or is disposed proximate to second spectral filter 344 that is opposite of edge 325E).

In some embodiments, the color filter material (e.g., red color filter material) for forming spectral filter 340 is formed of a photo-resistive material or a resin material containing red color agent such as a red pigment or red dye that transmits or passes red light (e.g., light having wavelength ranging from 600 nm to 750 nm) while reflecting, absorbing, or otherwise attenuating other colors of light (e.g., light outside of the 600 nm to 750 nm range). In illustrated embodiments, microlens material 330 (e.g., a polymer transparent through the visible range of wavelengths) is disposed between metal shield 325 and proximal metal grid segment MG-1 that separates microlens material 330 and adjacent color filters (e.g., spectral filter 342 corresponding to a green color filter) of a neighboring imaging pixel cell (e.g., QPD pixel cell 333G). In the same or other embodiments, microlens material 330 is disposed between spectral filter 340 and adjacent or neighboring color filters (e.g., spectral filter 342) of a neighboring imaging pixel cell (e.g. QPD pixel cell 333G).

In some embodiments, spectral filter 340 has a first vertical thickness H1 along a direction normal to the backside surface BS of semiconductor material 302 (e.g., depthwise direction). In some embodiments, first vertical thickness H1 is substantially (e.g., does not deviate but for due to manufacturing or processing limitations such as 10% or less, 5% or less, or the like) uniform throughout the first lateral width W_{S} of spectral filter 340. In the same or other embodiments, metal shield 325 has a second vertical thickness H2 along the direction normal to the backside surface BS. In some embodiments, a combined vertical thickness (e.g., thickness along the direction normal to the backside surface BS) of spectral filter 340 and metal shield 325 is the same as a third vertical thickness of an adjacent color filter included in an adjacent QPD pixel cell (e.g., third vertical thickness H3 of second spectral filter 344 included in QPD pixel cell 331G adjacent to PDAF pixel cell 320). In some embodiments, a top surface 340T of spectral filter 340 is flush with a top surface of an adjacent or interfacing color filter included in an adjacent QPD pixel cell (e.g., top surface 344T of second spectral filter 344 is flush with spectral filter 340) for processing consideration and to reduce the impact on sensitivity of the adjacent QPD pixel cells (e.g., QPD pixel cell 331G). In a different embodiment, the combined vertical thickness of spectral filter 340 and metal shield 325 is greater than third vertical thickness of the adjacent color filter included in the adjacent QPD pixel cell (third vertical thickness H3 of second spectral filter 344 included in QPD pixel cell 331G adjacent to PDAF pixel cell 320).

In the illustrated embodiment, spectral filter 340 extends laterally from edge 320E of PDAF pixel cell 320 (e.g., corresponding to an outer edge of spectral filter 340) a lateral width W_{S} toward a center of PDAF pixel cell 320. Spectral filter 340 extends from an edge 344E of second spectral filter 344 (e.g., a green color filter corresponding to second spectral filter 344 adjacent to a red color filter corresponding to spectral filter 340) toward a center of PDAF pixel cell 320. In some embodiments, spectral filter 340 abuts second spectral filter 344 (e.g., spectral filter 340 directly contacts second spectral filter 344).

In some embodiments, first lateral width W_{S} of spectral filter 340 is less than second lateral width W_{M} of metal shield 325 along the direction parallel to the backside surface Bs of semiconductor material 302 such that there is a gap between edge 340E of spectral filter 340 and edge 325E of metal shield 325 filled by microlens material 330. In some embodiments, spectral filter 340 is sandwiched between second spectral filter 344 and microlens material 330 to minimize sensitivity or angular selectivity impact on right photodiodes PDR. Arranging a gap between edge 340E of spectral filter 340 and edge 325E of metal shield 325 may help to reduce unintentional attenuation of light that is directed to uncovered photodiodes (e.g., right photodiodes PDR) of PDAF pixel cell 320 (e.g., to avoid reducing sensitivity of image signals generated by PDAF pixel cell 320 that are used for phase detection autofocus). In some embodiments, a ratio between first lateral width W_{S} of spectral filter 340 and second lateral width W_{M} of metal shield 325 is from 0.6 to 1.

In some embodiments, metal shield 325 may cover up to 50% of photosensitive region 309 or PDAF pixel cell 320. In such an embodiment, second lateral width W_{M} of metal shield 325 along the direction parallel to the backside surface BS is half of width W_{PDAF} of PDAF pixel cell 320. In some embodiments, the spectral filter 340 has an area coverage amount ranging from 30% to 50% of photosensitive region 309 (e.g., an area defined by width W_{PDAF} of PDAF pixel cell 320). In some embodiments, spectral filter 340 for PDAF pixel cell 320 may vary in lateral width (e.g., coverage amount) depending on a location within pixel cell array 300 and/or based on a position or orientation of metal shield 325 (e.g., left or right orientation that respectively cover left photodiodes PDL or right photodiodes PDR) to accommodate for a chief ray angle for the lens employed by the image sensor (e.g., the chief ray angle for a given pixel or pixel cell changes based on its relative position within pixel cell array 300).

In some embodiments, the dimension or coverage amount of spectral filter 340 may be configured based on target optical performance such as crosstalk level (e.g., acceptable level of crosstalk for second level pixels) and/or pixel sensitivity or angular selectivity for PDAF pixel cell 320. More specifically, third lateral width W_{GAP} of gap 341 may be held constant (e.g., substantially equal within limitations of manufacturing constraints) across pixel cell array 300 to improve pixel uniformity. In one embodiment, it may be preferable to limit a coverage amount of spectral filter 340 (e.g., to cover 30% of photosensitive region 309 defined by width W_{PDAF} of PDAF pixel cell 320) to avoid lowering angular selectivity of PDAF pixel cell 320. In the same or other embodiments, spectral filter 340 partially covers metal shield 325 (e.g., such that there is third lateral width W_{GAP} corresponding to a distance between edge 340E of spectral filter 340 and edge 325E of metal shield 325 along the direction parallel to the backside surface BS that is non-zero) to mitigate selectivity or sensitivity impact on PDAF pixel cell 320. In some embodiments, third lateral width W_{GAP} of gap 341 is configured to be at most about (e.g., within 10% or less) 0.4 times second lateral width W_{M} of metal shield 325 such that spectral filter 340 provides sufficient coverage for filtering out or removing reflected light with short wavelengths (e.g., blue or green light) for improving crosstalk.

In embodiments where spectral filter 340 of PDAF pixel cell 320 corresponds to a red color filter and neighboring or adjacent color filters of imaging pixel cells correspond to green or blue color filters (e.g., second spectral filter 344 of QPD pixel cell 331G corresponds to a green color filter), PDAF pixel cell 320 may reduce crosstalk of first, second, and third level pixels as well as corner pixels (see, e.g., FIG. 2A and associated discussion defining pixel levels relative to a given PDAF pixel cell). As illustrated, spectral filter 340 placed between microlens 350-1 and metal shield 325 causes portions or all of light 370 that is reflected from metal shield 325 to first be filtered by spectral filter 340 (e.g., only portions of reflected light having wavelength between 600 nm to 750 nm is allowed to pass through spectral filter 340). For example, reflected light 370R1 after propagating through spectral filter 340 would only have red light components as short light wavelength component (i.e., non-red light) is filtered or otherwise attenuated before reaching to neighboring imaging pixel cells (e.g., pixel cell 331G and/or 329B). The reflected light rays 370R2 and 370R3 generated from reflected light rays 370R1 propagating along a curvature of a microlens 350-2 subsequently enter respective color filters of neighboring imaging pixels (e.g., second spectral filter 344 corresponding to a green color filter and a blue color filter of QPD pixel cell 329B) before reaching or absorbed by respective photodiodes. Since reflected light rays 370R1 only has red light components after being filtered by spectral filter 340 on metal shield 325, reflected light rays 370R2 and 370R3 also only have red light components and thus would be attenuated or otherwise filtered by the green or blue color filters of the imaging pixel cells adjacent to PDAF pixel cell 320 (e.g., QPD pixel cells 329B and/or 331G). As such, PD crosstalk issues (e.g., crosstalk associated with second level pixels in particular) induced by metal shield 325 may be reduced.

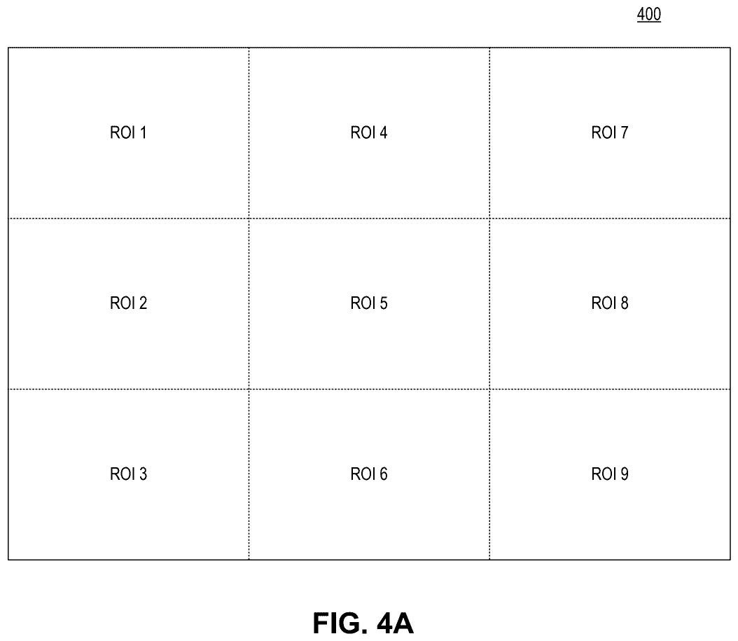

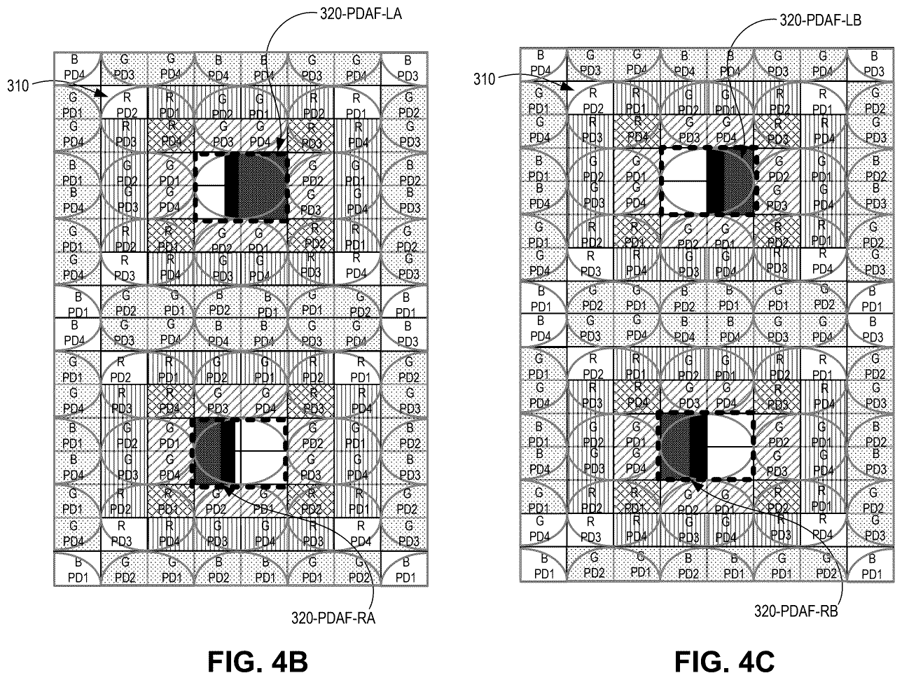

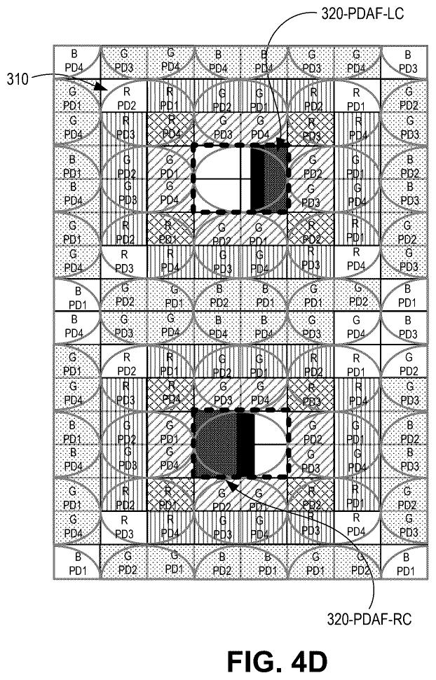

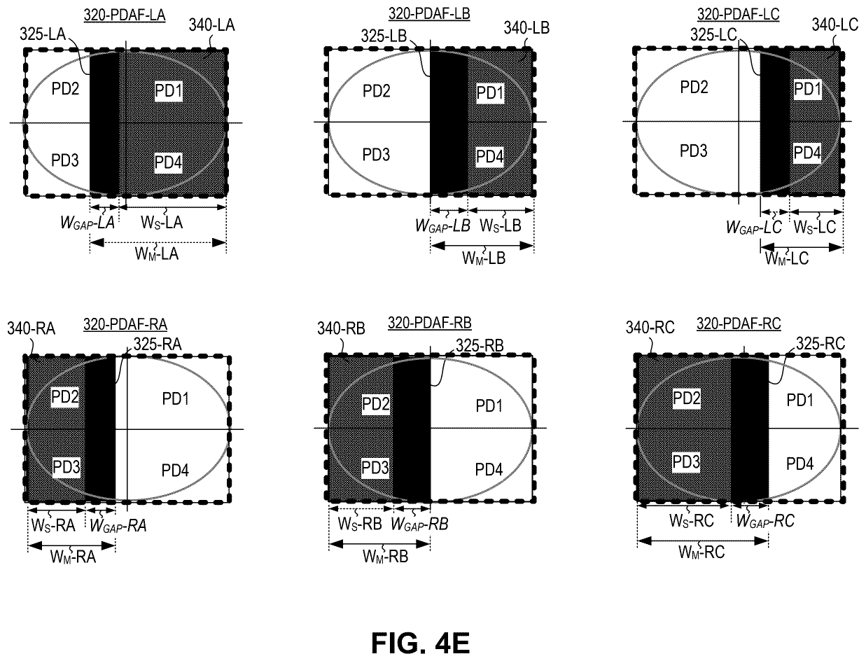

FIG. 4A illustrates an exemplary partition of pixel cell array 400 that includes a plurality of PDAF pixel cells 320, in accordance with teachings of the disclosure. More specifically, pixel cell array 400 is an example of how lateral widths of metal shield 325 and/or spectral filter 340 may be varied based on a position of a given PDAF pixel cell within pixel cell array 400 to accommodate chief ray angle. More specifically, the magnitude of the chief ray angle associated with the given PDAF pixel cell increases as the position of the given PDAF pixel cell deviates from a center of pixel cell array 400, which may impact the functionality of the given PDAF pixel cell (e.g., the asymmetry provided by the metal shield may be limited due to chief ray angle). Thus, in order to compensate or otherwise accommodate for chief ray angle, embodiments of the disclosure vary the lateral widths of the metal shield 325 and/or spectral filter 340 of the plurality of PDAF pixel cells 320 based on a position of a given PDAF pixel cell within pixel cell array 400. In the illustrated embodiment, pixel cell array 400 is partitioned into 9 regions of interest (e.g., ROI 1 through ROI 9) for the following discussion of placement and configuration of metal shield 325 and/or spectral filter 340 included in plurality of PDAF pixel cells 320 illustrated in FIG. 4B-4E to accommodate chief ray angle.

Referring back to FIG. 4A, ROI 1, ROI 2, and ROI 3 correspond to location in a left part of pixel cell array 400 with respect to a center of pixel cell array 400 where the chief ray angle is non-zero degrees in a negative direction. For example, ROI 1 may refer to a top-left corner of pixel cell array 400. ROI 2 refers to center-left region of pixel cell array 400. ROI 3 refers to bottom-left corner of pixel cell array 400. ROI 4, ROI 5 ROI 6 correspond to a center region of pixel cell array 400 where chief ray angle is 0°. ROI 7, ROI 8, and ROI 9 correspond to a right part of pixel cell array 400 with respect to the center of pixel cell array 400 where chief ray angle is non-zero degrees in a positive direction. In some embodiments, ROI 1, ROI 2, and ROI 3 correspond to a location in a leftmost part of pixel cell array 400 proximate to a perimeter boundary of pixel cell array 400 where the magnitude of the chief ray angle is the largest in the negative direction. In the same or other embodiments, ROI 7, ROI 8, and ROI 9 correspond to a location in the rightmost part of pixel cell array 400 proximate to a perimeter boundary of pixel cell array 400 where the magnitude of the chief ray angle is the largest in the positive direction.

FIG. 4B illustrates a first pair of PDAF pixel cells including a left-oriented PDAF pixel cell 320-PDAF-LA and a right-oriented PDAF pixel cell 320-PDAF-RA located within any of ROI 1, ROI 2, or ROI 3 illustrated in FIG. 4A, in accordance with teachings of the disclosure. In some embodiments, a metal shield (e.g., 325-LA or 325-RA illustrated in FIG. 4E) and a spectral filter (e.g., 340-LA or 340-RA) included in PDAF pixel cells 320-PDAF-LA and 320-PDAF-RA may be configured to accommodate a chief ray angle for a lens employed by the image sensor (e.g., −33°).

FIG. 4C illustrates a second pair of PDAF pixel cells including a left-oriented PDAF pixel cell 320-PDAF-LB and a right-oriented PDAF pixel cell 320-PDAF-RB located within any of ROI 4, ROI 5, or ROI 6 illustrated in FIG. 4A, in accordance with teachings of the disclosure. In some embodiments, a metal shield (e.g., 325-LB or 325-RB illustrated in FIG. 4E) and a spectral filter (e.g., 340-LB or 340-RB) included in PDAF pixel cells 320-PDAF-LB and 320-PDAF-RB may be configured to accommodate a chief ray angle for a lens employed by the image sensor (e.g., 0°).

FIG. 4D illustrates a third pair of PDAF pixel cells including a left-oriented PDAF pixel cell 320-PDAF-LC and a right-oriented PDAF pixel cell 320-PDAF-RC located within any of ROI 7, ROI 8, or ROI 9 illustrated in FIG. 4A, in accordance with teachings of the disclosure. In some embodiments, a metal shield (e.g., 325-LC or 325-RC illustrated in FIG. 4E) and a spectral filter (e.g., 340-LC or 340-RC) included in PDAF pixel cells 320-PDAF-LC and 320-PDAF-RC may be configured to accommodate a chief ray angle for a lens employed by the image sensor (e.g., 33°).

FIG. 4E illustrates a more detailed view of left and right oriented PDAF pixel cells illustrated in FIG. 4B-4E, in accordance with teachings of the disclosure. Left oriented PDAF pixel cells include 320-PDAF-LA, 320-PDAF-LB, and 320-PDAF-LC and right oriented PDAF pixel cells include 320-PDAF-RA, 320-PDAF-RB, and 320-PDAF-RC, which may be variations of plurality of PDAF pixel cells 320 illustrated in FIG. 3. Accordingly, it is appreciated that the left and right oriented PDAF pixel cells illustrated in FIG. 4A-4E may have the same or similar features (e.g., descriptions of like-labeled features may similarly apply). For example, PDAF pixel cells 320-PDAF-LA, 320-PDAF-LB, and 320-PDAF-LC respectively include metal shields (e.g., 325-LA with lateral width W_{M}-LA, 325-LB with lateral width W_{M}-LB, and 325-LC with lateral width W_{M}-LC) and spectral filters (e.g., 340-LA with lateral width W_{S}-LA, 340-LB with lateral width W_{S}-LB, and 340-LC with lateral width W_{S}-LC) comparable to metal shield 325 and spectral filter 340 illustrated in FIG. 3. Similarly, PDAF pixel cells 320-PDAF-RA, 320-PDAF-RB, and 320-PDAF-RC respectively include metal shields (e.g., 325-RA with lateral width W_{M}-RA, 325-RB with lateral width W_{M}-RB, and 325-RC with lateral width W_{M}-RC) and spectral filters (e.g., 340-RA with lateral width W_{S}-RA, 340-RB with lateral width W_{S}-RB, and 340-RC with lateral width W_{S}-RC) comparable to metal shield 325 and spectral filter 340 illustrated in FIG. 3. It is further appreciated that lateral widths of uncovered portions of respective metal shields (e.g., gaps) resultant of partial coverage provided by the spectral filters of PDAF pixel cells 320-PDAF-LA, 320-PDAF-LB, 320-PDAF-LC, 320-PDAF-RA, 320-PDAF-RB, and 320-PDAF-RC are respectively illustrated as W_{GAP}-LA, W_{GAP}-LB, W_{GAP}-LC, W_{GAP}-RA, W_{GAP}-RB, and W_{GAP}-RC.

In reference to PDAF pixel cells 320-PDAF-LA and 320-PDAF-RC, metal shields 325-LA and 325-RC for light shielding may be enlarged (e.g., based on W_{M}-LA and W_{M}-RC) to cover more than 50% but less than 100% of a pixel region (e.g., defined by photodiodes PD1, PD2, PD3, and PD4 such that two photodiodes in a same column are completely covered while two photodiodes in an adjacent column are only partially covered by the metal shield) to detect left (e.g., for 320-PDAF-LA) or right (e.g., for 320-PDAF-RC) image signal information for phase detection autofocus. In reference to PDAF pixel cells 320-PDAF-RA and 320-PDAF-LC, metal shields 325-RA and 325-LC for light shielding may be reduced (e.g., based on W_{M}-RA and W_{M}-LC) to cover more than 0% but less than 50% of a pixel region (e.g., defined by photodiodes PD1, PD2, PD3, and PD4 such that two photodiodes in a same column are only partially covered while two photodiodes in an adjacent column are not covered by the metal shield) to detect left (e.g., for 320-PDAF-LC) or right (e.g., for 320-PDAF-RA) image signal information for phase detection autofocus. In reference to PDAF pixel cells 320-PDAF-LB and 320-PDAF-RB, metal shields 325-LB and 325-RB for light shielding may cover (e.g., based on W_{M}-LB and W_{M}-RB) 50% of a pixel region (e.g., defined by photodiodes PD1, PD2, PD3, and PD4 such that two photodiodes in a same column are completely covered while two photodiodes in an adjacent column are not covered by the metal shield) to detect left (e.g., for 320-PDAF-LB) or right (e.g., for 320-PDAF-RB) image signal information for phase detection autofocus.

It is appreciated that a pair of differently oriented (e.g., left and right oriented) PDAF pixel cells located in a same region of interest (e.g., pixel cell 320-PDAF-LA and 320-PDAF-RA, which may be collectively located in one of ROI 1, ROI 2, or ROI 3 illustrated in FIG. 4A) may be used as an autofocus point for said region of interest or location (e.g., to determine whether said region of interest or location is in focus and/or how much lens displacement is needed to focus said region of interest or location). It is further appreciated that the pair of differently oriented PDAF pixel cells located in the same region of interest are separated from one another by at least one QPD imaging pixel cell as illustrated in FIG. 4B-4D.

Referring back to FIG. 4E, it is appreciated that in some embodiments, a relative amount of metal shields (e.g., 325-LA, 325-LB, 325-LC, 325-RA, 325-RB, and 325-RC) uncovered by spectral filters (e.g., 340-LA, 340-LB, 340-LC, 340-RA, 340-RB, and 340-RC) may be held constant (e.g., substantially equal within limitations of manufacturing constraints). In other words, in some embodiments third lateral widths (e.g., W_{GAP}-LA, W_{GAP}-LB, W_{GAP}-LC, W_{GAP}-RA, W_{GAP}-RB, and W_{GAP}-RC) is held constant across pixel cell array 400. For example, as a first lateral width (e.g., W_{M}-LA, W_{M}-LB, W_{M}-LC, W_{M}-RA, W_{M}-RB, and W_{M}-RC) of the metal shields is adjusted based on an orientation and position of a given PDAF pixel cell within pixel cell array 400, then a second lateral width (e.g., W_{S}-LA, W_{S}-LB, W_{S}-LC, W_{S}-RA, W_{S}-RB, and W_{S}-RC) of the spectral filters may also be adjusted while third lateral widths (e.g., W_{GAP}-LA, W_{GAP}-LB, W_{GAP}-LC, W_{GAP}-RA, W_{GAP}-RB, and W_{GAP}-RC) of gaps is held constant for all PDAF pixel cells included in pixel cell array 400.

As illustrated in FIG. 4E, PDAF pixel cells 320-PDAF-LA, 320-PDAF-LB, and 320-PDAF-LC have a same orientation, but represent different positions within a pixel cell array and thus are associated with different chief ray angles. For example, 320-PDAF-LB is representative of a chief ray angle (e.g., 0°) greater than a chief ray angle (e.g., −33°) associated with 320-PDAF-LA but less than a chief ray angle (e.g., 33°) associated with 320-PDAF-LC. In such an embodiment, a lateral width W_{M}-LB of metal shield 325-LB is greater than a lateral width W_{M}-LC of metal shield 325-LC but less than a lateral width W_{M}-LA of metal shield 325-LA. In the same or another embodiment, a lateral width W_{S}-LB of spectral filter 340-LB is greater than a lateral width W_{S}-LC of spectral filter 340-LC but less than a lateral width W_{S}-LA of spectral filter 340-LA. In the same or other embodiments, third lateral widths W_{GAP}-LA, W_{GAP}-LB, and W_{GAP}-LC of uncovered portions of metal shields 325-LA, 325-LB, and 325-LC is the same.

As illustrated in FIG. 4E, PDAF pixel cells 320-PDAF-RA, 320-PDAF-RB, and 320-PDAF-RC have a same orientation, but represent different positions within a pixel cell array and thus are associated with different chief ray angles. For example, 320-PDAF-RB is representative of a chief ray angle (e.g., 0°) greater than a chief ray angle (e.g., −33°) associated with 320-PDAF-RA but less than a chief ray angle (e.g., 33°) associated with 320-PDAF-RC. In such an embodiment, a lateral width W_{M}-RB of metal shield 325-RB is less than a lateral width W_{M}-RC of metal shield 325-RC but greater than a lateral width W_{M}-RA of metal shield 325-RA. In the same or another embodiment, a lateral width W_{S}-RB of spectral filter 340-RB is less than a lateral width W_{S}-RC of spectral filter 340-RC but greater than a lateral width W_{S}-RA of spectral filter 340-RA. In the same or other embodiments, third lateral widths W_{GAP}-RA, W_{GAP}-RB, and W_{GAP}-RC of uncovered portions of metal shields 325-RA, 325-RB, and 325-RC is the same. In some embodiments, paired PDAF pixel cells (e.g., a first pair including 320-PDAF-LA and 320-PDAF-RA, a second pair including 320-PDAF-LB and 320-PDAF-RB, and/or a third pair including 320-PDAF-LC and 320-PDAF-RC) have a same lateral width for uncovered portions of the respective metal shields.

In some embodiments, each individual pair of PDAF pixel cells (e.g., the first pair including 320-PDAF-LA and 320-PDAF-RA, the second pair including 320-PDAF-LB and 320-PDAF-RB, and/or the third pair including 320-PDAF-LC and 320-PDAF-RC) are each individually arranged to be laterally surrounded by imaging pixel cells (e.g., QPD pixel cells 310 illustrated in FIG. 4B-4D, which may correspond to plurality of QPD pixel cells 210 illustrated in FIG. 2A-2B). Groups of pixels or photodiodes included in QPD pixel cells 310 surrounding the first pair, second pair, and/or third pair of PDAF pixel cells may be classified as first level pixels (e.g., first level pixels 230 illustrated in FIG. 2A-2B), corner pixels (e.g., corner pixels 240 illustrated in FIG. 2A-2B), second level pixels (e.g., second level pixels 250 illustrated in FIG. 2A-2B), or third level pixels (e.g., third level pixels 260 illustrated in FIG. 2A-2B).

In some embodiments, spectral filter 340 (e.g., 340-LA, 340-LB, 340-LC, 340-RA, 340-RB, and/or 340-RC), which partially covers underlying metal shield 325 (e.g., 325-LA, 325LB, 325-LC, 325-RA, 325-RB, and/or 325-RC) may be shifted towards a center of a photosensitive region (e.g., where PD1, PD2, PD3, and PD4 meet) of a given PDAF pixel cell to address color imbalance associated with first level pixels. For example, an edge of spectral filter 340 proximal to the center of the photosensitive region of the given PDAF pixel cell may be aligned with a corresponding edge of the metal shield 325 proximal to the center of the photosensitive region of the given PDAF pixel cell. In other words, edges of spectral filter 340 and metal shield 325 closest to a center or midpoint of a given PDAF pixel cell are aligned.

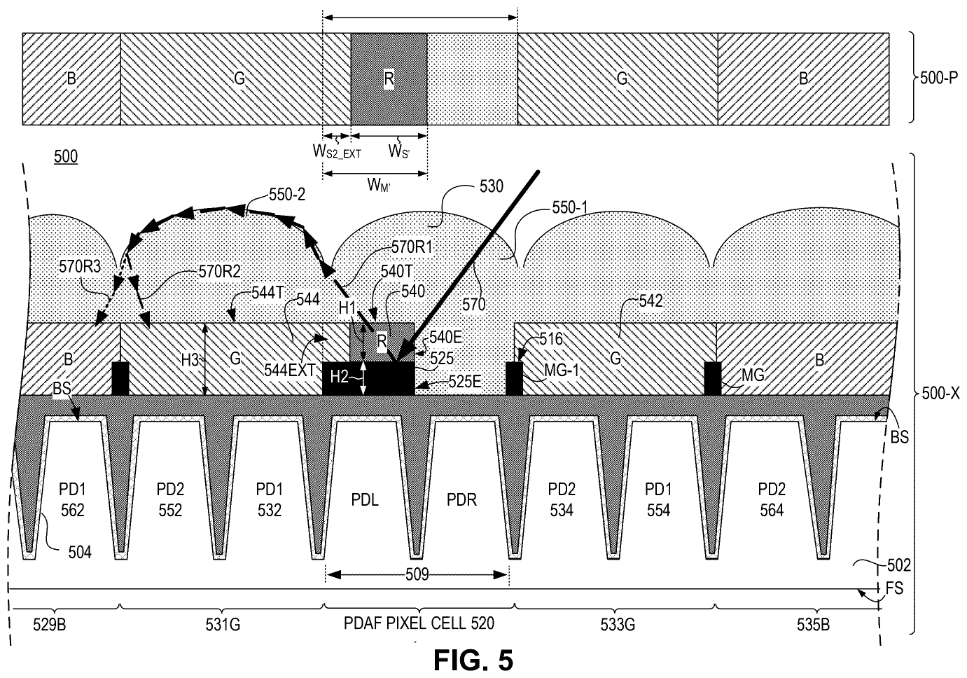

FIG. 5 illustrates a cross-sectional view 500-X and a plan view 500-P of a partial pixel cell array of an image sensor including a PDAF pixel cell 520 with reduced induced crosstalk, in accordance with teachings of the disclosure. PDAF pixel cell 520 represents an improved phase detection structure relative to PDAF pixel cell 220 illustrated in FIG. 2A-2B. In the illustrated embodiment, PDAF pixel cell 520 includes a plurality of photodiodes, including left photodiodes PDL and right photodiodes PDR (e.g., first, second, third, and forth photodiodes arranged in a two-by-two array) surrounded by imaging pixels (e.g., pixel cell 529B including photodiode PD1 562, pixel cell 531G including photodiode PD2 552 and PD1 532, pixel cell 533G including photodiode PD2 534 and PD1 554, and pixel cell 535B including photodiode 564) formed within semiconductor material 502. PDAF pixel cell 520 further includes metal shield 525, spectral filter 540, and microlens 550-1.

PDAF pixel cell 520 includes a photosensitive region 509 (e.g., defined by isolation structure 504) formed in semiconductor material 502 corresponding to regions where left photodiodes PDL and right photodiodes PDR are located (e.g., doped regions of semiconductor material 502 that collectively form left photodiodes PDL and right photodiodes PDR). Semiconductor material 502 includes front side surface FS and the backside surface BS opposite of the front side FS. Metal shield 525 is disposed between microlens 550-1 and photosensitive region 509 (e.g., to block incident light from reaching left photodiodes PDL or right photodiodes PDR depending on an orientation of PDAF pixel cell 520). In the illustrated embodiment, pixel cell array 500 includes isolation structure 504 (e.g., a plurality of deep trench isolation structures) formed in semiconductors material 502 to provide isolation between individual photodiodes (e.g., left photodiodes PDL and right photodiodes PDR may be isolation from each other via isolation structure 504) included in phase detection autofocus pixel cells and normal imaging pixel cells (e.g., pixel cells 529B, 531G, 533G, 535G, and so on). In some embodiments, a metal grid 516 is formed between individual color filters (“R”, “G”, or “B”) of the color filter array. In the same or other embodiments, metal grid 516 may be vertically aligned with isolation structure 504 to form a plurality of apertures defining light exposure or sensing regions of individual pixels or pixel cells included in pixel cell array 500. Apertures formed by metal grid 516 may be filled with individual color filters such that a given pixel or pixel cell is associated with a predetermined color (e.g., red, green, or blue). Metal grid 516 includes a plurality metal grid segments MG separating each individual color filter. QPD pixel cell 531G includes second spectral filter 544 (e.g., a green color filter) with microlens 550-2 optically aligned with underlying photodiodes (i.e., a two-by-two array of photodiodes including PD1 5332 and PD2 552). QPD pixel cell 533G includes another spectral filter 542 (e.g., a green color filter) with a corresponding microlens optically aligned with underlying photodiodes (i.e., a two-by-two array of photodiodes including PD1 554 and PD2 534).

PDAF pixel cell 520 includes many similar features as PDAF pixel cell 320 illustrated in FIG. 3 and thus may include like-labeled elements (e.g., semiconductor material 502 may correspond to semiconductor material 302, isolation structure 504 may correspond to isolation structure 504, microlens 550-1 may correspond to microlens 350-1, and so on) and thus may have the same or similar features. One difference is spectral filter 540 is shifted towards a center of PDAF pixel cell 520 (e.g., based on lateral dimensions of photosensitive region 509 and/or a width W_{PDAF′} of PDAF pixel cell 520) such that edge 540E is aligned with an inner edge 525E of metal shield 525. In the illustrated embodiment of FIG. 5, edge 525E of metal shield 525 corresponds to an inner edge opposite of an outer edge of metal shield 525. It is appreciated that the inner edge of metal shield (i.e., edge 525E) is disposed closer to a center of PDAF pixel cell 520 (e.g., based on lateral dimensions of photosensitive region 509 and/or a width W_{PDAF′} of PDAF pixel cell 520).

However, since spectral filter 540 still only partially cover metal shield 525 a portion of metal shield 525 remains uncovered by spectral filter 540 (e.g., proximate to an outer edge of metal shield 525). In the illustrated embodiment, an adjacent color filter is configured to extend over and onto the uncovered portion of metal shield 525. In other words, the gap (i.e., uncovered portion of metal shield 525 due to partial coverage provided by spectral filter 540) is filled by a second spectral filter (e.g., spectral filter 544) having a second photoresponse (e.g., a photoresponse associated with a green or blue color filter) different from a first photoresponse (e.g., photoresponse associated with a red color filter) of spectral filter 540. In the illustrated embodiment, second spectral filter 544, or more specifically, an extended portion 544EXT of second spectral filter 544, is disposed between microlens 550-1 and metal shield 525. In some embodiments, extended portion 544EXT of second spectral filter 544 is adjacent to spectral filter 540. In the same or other embodiments, extended portion 544EXT of second spectral filter 544 is flush or otherwise directly contacts spectral filter 540.

In some embodiments, a corresponding lateral width W_{S2_EXT} of second spectral filter 544 disposed over metal shield 525 (e.g., extended portion 544EXT) along the direction parallel to the backside surface BS is less than a first lateral width W_{S′} of spectral filter 540. In the same or other embodiments, a vertical thickness (e.g., H1) of spectral filter 540 is substantially (e.g., within manufacturing tolerances such as 10%) uniform throughout first lateral width W_{S′} of spectral filter 540. In some embodiments, a vertical thickness of second spectral filter 544 along the direction parallel to the backside surface BS is not uniform (e.g., second spectral filter 544 has a vertical thickness of H3 for a portion not disposed over metal shield 525 and a vertical thickness H1 for extended portion 544EXT disposed over metal shield 525). In some embodiments, a pixel associated with PD1 532 included in pixel cell 531G corresponds to a first level pixel that is row or column adjacent to PDAF pixel cell 520.

As illustrated in FIG. 5, a position of spectral filter 540 is shifted toward a center of a pixel region (e.g., based on photosensitive region 509) of PDAF pixel 520 and away from microlens 550-2 of the adjacent QPD pixel (e.g., pixel associated with PD1 532 included in QPD pixel cell 541G) that is configured as a normal imaging pixel. Edge 540E of spectral filter 540 may be aligned with edge 525E of metal shield 525 used for blocking light (e.g., that would otherwise be incident on left photodiodes PDL). In some embodiments, edge 540E of spectral filter 540 and edge 525E of metal shield 525 may be vertically aligned with a centerline of a deep trench isolation structure included in isolation structure 504 that separates left photodiodes PDL and right photodiodes PDR of PDAF pixel cell 520 to reduce an impact on angular selectivity of PDAF pixel cell 520.

Lateral width W_{S′} of spectral filter 540 may be less than lateral width W_{M′} of metal shield 525. For example, lateral width W_{S′} of spectral filter 540 may be about 60% of lateral width W_{M′} of metal shield 525. In some embodiments, lateral width W_{S′} of spectral filter 540 may range from about 60% to 100% of lateral width W_{M′} of metal shield 525.

In the illustrated embodiment, second spectral filter 544 is disposed between microlens 550-2 and photodiodes (e.g., a two-by-two array of photodiodes including PD1 532 and PD2 552) included in QPD pixel cell 531G adjacent to PDAF pixel cell 520. Second spectral filter 544 includes extended portion 544EXT that extends over the pixel region (e.g., photosensitive region 509) of PDAF pixel cell 520. Extended portion 544EXT of spectral filter 544 may be formed or otherwise disposed on metal shield 525. That is, a portion of second spectral filter 544 (e.g., extended portion 544EXT) is formed between microlens 550-1 and metal shield 525. Put in another way, second spectral filter 544 includes a first portion formed or otherwise disposed between microlens 550-2 and photodiodes included in QPD pixel cell 531G adjacent to PDAF pixel cell 520 and a second portion formed or otherwise disposed between microlens 550-1 and photodiodes included in PDAF pixel cell 520 (e.g., left photodiodes PDL) to increase light sensitivity of the adjacent QPD pixel cell (e.g., QPD pixel cell 531G) and further reduce PD crosstalk (e.g., crosstalk included by PDAF pixel cell 520).

In some embodiments, spectral filter 540 is disposed on metal shield 525 between extended portion 544EXT of second spectral filter 5444 and microlens material 530 (e.g., a transparent polymer) of microlens 550-1. In the same or other embodiments, microlens material 530 is disposed between metal shield 525 and a metal grid segment MG-1. In some embodiments, microlens material 530 is further disposed between the metal shield 525 and another spectral filter 542 included in another adjacent QPD pixel cell (e.g., QPD pixel cell 533G such that QPD pixel cell 531G, PDAF pixel cell 520, and QPD pixel c ell 533G are disposed along a same row or column) positioned on a right side of PDAF pixel cell 520 (e.g., closer to right photodiodes PDR relative to left photodiodes PDL).

In an embodiment, extended portion 544EXT of second spectral filter 544 has a lateral width W_{S2_EXT} that is less than a lateral width W_{M} of metal shield 525 in the direction parallel to the backside surface BS of semiconductor material 502. In some embodiments, lateral width W_{S2_EXT} of extended portion 544EXT is greater than 0 but less than lateral width W_{S′} of spectral filter 540. In some embodiments, a combination of lateral width W_{S2_EXT} of extended portion 544EXT and lateral width W_{S} of spectral filter 540 is substantially (e.g., within manufacturing tolerances such as 10%) the same as lateral width W_{M} of metal shield 525. In some embodiments, lateral width W_{S2_EXT} of extended portion 544EXT may be kept constant (e.g., similar to uncovered portion of metal shield 325 illustrated in FIG. 4E). In some embodiments, width W_{S2_EXT} of extended portion 544EXT may vary or is otherwise based on lateral width W_{S} of spectral filter 540.

In some embodiments, extended portion 544EXT of second spectral filter 544 may cover an area of photosensitive region 509 of PDAF pixel cell 520 from 1% to 20%. In some embodiments, lateral width W_{S2_EXT} of extended portion 544EXT of second spectral filter 544 is greater than 0 but less than 0.4 times lateral width W_{M′} of metal shield 525 while lateral width W_{S} of spectral filter 540 is from 0.6 to 0.9 times lateral width W_{M′} of metal shield 525. In some embodiments, lateral width W_{S2_EXT} of extended portion 544EXT and lateral width W_{S′} of spectral filter 540 may be configured based on a width W_{PDAF′} of PDAF pixel cell 520.

In operation, extended portion 544EXT allows a portion of light directed through microlens 550-1 to be incident on or otherwise directed to photodiodes (e.g., first level pixel such as pixel associated with PD1 532) included in the QPD pixel cell adjacent to PDAF pixel cell 520 (e.g., QPD pixel cell 531G). In such a manner, PD crosstalk may be reduced and pixel uniformity may be improved. In some embodiments, second spectral filter 544 including extended portion 544EXT may be formed of a green color filter material. In one example, the green color filter material is formed a photo-resistive material or a resin material containing green color agent such as green pigment or green dye) that transmits or passes green light (e.g., light having wavelength ranging from 500 nm to 570 nm) while reflecting and/or absorbing other colors of light. In the same or different embodiments, spectral filter 540 may be formed of a red color filter material. In one example, the red color filter material is formed of a photo-resistive material or a resin material containing red color agent such as red pigment or red dye) that transmits or passes red light (e.g., light having wavelength ranging from 600 nm to 750 nm) while reflecting and/or absorbing other colors of light.

In some embodiments, second spectral filter 544 including extended portion 544EXT may be formed in the same process as green color filters for other “green” QPD pixels sharing a common mask. The formation of second spectral filter 544 including extended portion 544EXT may occur after the formation of metal shield 525 but prior to deposition of microlens material 530 for forming a microlens array including microlens 550-1 and 550-2. In some embodiments, formation of second spectral filter 544 including extended portion 544EXT may occur before or after formation of spectral filter 540.

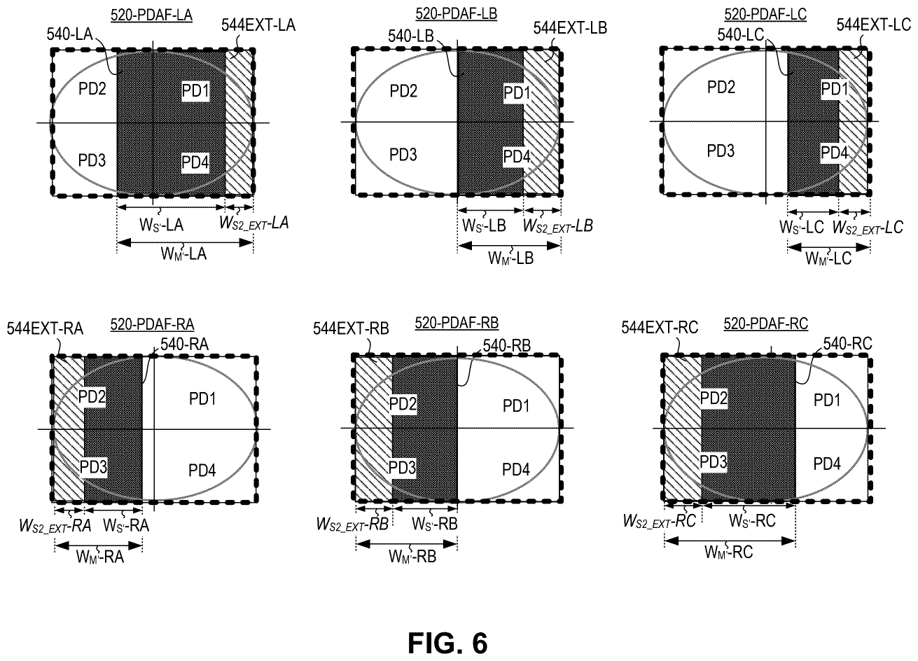

FIG. 6 illustrates left and right oriented PDAF pixel cells with two spectral filters disposed over corresponding metal shields, in accordance with teachings of the disclosure. Left oriented PDAF pixel cells include 520-PDAF-LA, 520-PDAF-LB, and 520-PDAF-LC and right oriented PDAF pixel cells include 520-PDAF-RA, 520-PDAF-RB, and 520-PDAF-RC, which may be variations of plurality of PDAF pixel cells 520 illustrated in FIG. 5 and disposed across a pixel array in similar manner as illustrated in FIG. 4B-4D. Accordingly, it is appreciated that the left and right oriented PDAF pixel cells illustrated in FIG. 6 may have the same or similar features (e.g., descriptions of like-labeled features may similarly apply). For example, PDAF pixel cells 520-PDAF-LA, 520-PDAF-LB, and 520-PDAF-LC respectively include metal shields (e.g., 525-LA with lateral width W_{M′}-LA, 525-LB with lateral width W_{M′}-LB, and 525-LC with lateral width W_{M′}-LC) and spectral filters (e.g., 540-LA with lateral width W_{S′}-LA, 540-LB with lateral width W_{S′}-LB, and 540-LC with lateral width W_{S′}-LC) comparable to metal shield 525 and spectral filter 540 illustrated in FIG. 5. Similarly, PDAF pixel cells 520-PDAF-RA, 520-PDAF-RB, and 520-PDAF-RC respectively include metal shields (e.g., 525-RA with lateral width W_{M′}-RA, 525-RB with lateral width W_{M′}-RB, and 525-RC with lateral width W_{M′}-RC) and spectral filters (e.g., 540-RA with lateral width W_{S′}-RA, 540-RB with lateral width W_{S′}-RB, and 540-RC with lateral width W_{S′}-RC) comparable to metal shield 525 and spectral filter 540 illustrated in FIG. 5. It is further appreciated that lateral widths of extended portions (e.g., 544EXT-LA, 544EXT-LB, 544EXT-LC, 544EXT-RA, 544EXT-RB, and 544EXT-RC) of second spectral filter 544 having respective lateral widths (e.g., 544_{S2_EXT}-LA, 544_{S2_EXT}-LB, 544_{S2_EXT}-LC, 544_{S2_EXT}-RA, 544_{S2_EXT}-RB, and 544_{S2_EXT}-RC) are comparable to extended portion 544EXT of FIG. 5.

It is appreciated that left oriented PDAF pixel cells 520-PDAF-LA, 520-PDAF-LB, and 520-PDAF-LC and right oriented PDAF pixel cells 520-PDAF-RA, 520-PDAF-RB, and 520-PDAF-RC are representative of PDAF pixel cells configured based on an orientation and position within a pixel cell array. For example, in reference to FIG. 4A, PDAF pixel cells 520-PDAF-LA and 520-PDAF-RA may be positioned within ROI 1, ROI 2, or ROI 3. In another example, PDAF pixel cells 520-PDAF-LB and 520-PDAF-RB may be positioned within ROI 4, ROI 5, or ROI 6. In another example PDAF pixel cells 520-PDAF-LC and 520-PDAF-RC may be positioned within ROI 7, ROI 8, or ROI 9. Put in another way, PDAF pixel cells 520-PDAF-LB and 520-PDAF-RB are associated with a chief ray angle (e.g., 0°) greater than a chief ray angle associated with PDAF pixel cells 520-PDAF-LA and 520-PDAF-RA (e.g., −33°) but less than a chief ray angle associated with PDAF pixel cells 520-PDAF-LC and 520-PDAF-RC (e.g., 33°).

In reference to PDAF pixel cells 520-PDAF-LA and 520-PDAF-RC, metal shields 525-LA and 525-RC for light shielding may be enlarged (e.g., based on W_{M′}-LA and W_{M′}-RC) to cover more than 50% but less than 100% of a pixel region (e.g., defined by photodiodes PD1, PD2, PD3, and PD4 such that two photodiodes in a same column are completely covered while two photodiodes in an adjacent column are only partially covered by the metal shield) to detect left (e.g., for 520-PDAF-LA) or right (e.g., for 520-PDAF-RC) image signal information for phase detection autofocus. In reference to PDAF pixel cells 520-PDAF-RA and 520-PDAF-LC, metal shields 525-RA and 525-LC for light shielding may be reduced (e.g., based on W_{M′}-RA and W_{M′}-LC) to cover more than 0% but less than 50% of a pixel region (e.g., defined by photodiodes PD1, PD2, PD3, and PD4 such that two photodiodes in a same column are only partially covered while two photodiodes in an adjacent column are not covered by the metal shield) to detect left (e.g., for 520-PDAF-LC) or right (e.g., for 520-PDAF-RA) image signal information for phase detection autofocus. In reference to PDAF pixel cells 520-PDAF-LB and 520-PDAF-RB, metal shields 525-LB and 525-RB for light shielding may cover (e.g., based on W_{M′}-LB and W_{M′}-RB) 50% of a pixel region (e.g., defined by photodiodes PD1, PD2, PD3, and PD4 such that two photodiodes in a same column are completely covered while two photodiodes in an adjacent column are not covered by the metal shield) to detect left (e.g., for 520-PDAF-LB) or right (e.g., for 520-PDAF-RB) image signal information for phase detection autofocus. In one embodiment, spectral filters 540-LB and 540-RB may be configured to cover about (e.g., within 10% or otherwise based on manufacturing tolerances) 60% of an area of metal shields 525-LB and 525-RB, respectively, and extended portions 544EXT-LB and 544EXT-RB are configured to cover the remaining 40% area of metal shields 525-LB and 525-RB, respectively.

It is appreciated that a pair of differently oriented (e.g., left and right oriented) PDAF pixel cells located in a same region of interest (e.g., pixel cell 520-PDAF-LA and 520-PDAF-RA, which may be collectively located in one of ROI 1, ROI 2, or ROI 3) may be used as an autofocus point for said region of interest or location (e.g., to determine whether said region of interest or location is in focus and/or how much lens displacement is needed to focus said region of interest or location). It is further appreciated that the pair of differently oriented PDAF pixel cells located in the same region of interest are separated from one another by at least one QPD imaging pixel cell.

In some embodiments, spectral filters, extended portions of second spectral filters, and metal shields for pairs of PDAF pixel cells (e.g., a first pair including 520-PDAF-LA and 520-PDAF-RA, a second pair including 520-PDAF-LB and 520-PBAR-RB, and a third pair including 520-PDAF-LC and 520-PDAF-RC) may be configured or arranged based on an incident angle of light desired for an adjacent QPD pixel (e.g., first level pixel such as pixel associated with PD1 532 of pixel cell 531G illustrated in FIG. 5) to receive.

Referring to FIG. 6, it is appreciated that in some embodiments, a relative coverage amount of metal shields (e.g., 525-LA, 525-LB, 525-LC, 525-RA, 525-RB, and 525-RC) provided by extended portions (e.g., 544EXT-LA, 544EXT-LB, 544EXT-LC, 544EXT-RA, 544EXT-RB, and 544EXT-RC) of second spectral filters may be held constant (e.g., substantially equal within limitations of manufacturing constraints) for each PDAF pixel cell included in pixel cell array 500. For example, first lateral widths (e.g., W_{M′}-LA, W_{M′}-LB, W_{M′}-LC, W_{M′}-RA, W_{M′}-RB, and W_{M′}-RC) of metal shields and second lateral widths (e.g., W_{S′}-LA, W_{S′}-LB, W_{S′}-LC, W_{S′}-RA, W_{S′}-RB, and W_{S′}-RC) of spectral filters may be adjusted based on an orientation and position of a given PDAF pixel cell (e.g., to accommodate chief ray angle) within pixel cell array 500 while third lateral widths (e.g., 544_{S2_EXT}-LA, 544_{S2_EXT}-LB, 544_{S2_EXT}-LC, 544_{S2_EXT}-RA, 544_{S2_EXT}-RB, and 544_{S2_EXT}-RC) of extended portions (e.g., 544EXT-LA, 544EXT-LB, 544EXT-LC, 544EXT-RA, 544EXT-RB, and 544EXT-RC) of second spectral filters are held constant for each PDAF pixel cell included in pixel cell array 500.

As illustrated, PDAF pixel cells 520-PDAF-RA, 520-PDAF-RB, and 520-PDAF-RC have a same orientation, but represent different positions within a pixel cell array and thus are associated with different chief ray angles. For example, 520-PDAF-RB is representative of a chief ray angle (e.g., 0°) greater than a chief ray angle (e.g., −33°) associated with 520-PDAF-RA but less than a chief ray angle (e.g., 33°) associated with 520-PDAF-RC. In such an embodiment, a lateral width W_{M′}-RB of metal shield 525-RB is less than a lateral width W_{M′}-RC of metal shield 525-RC but greater than a lateral width W_{M′}-RA of metal shield 525-RA. In the same or another embodiment, a lateral width W_{S′}-RB of spectral filter 540-RB is less than a lateral width W_{S′}-RC of spectral filter 540-RC but greater than a lateral width W_{S′}-RA of spectral filter 540-RA. In the same or other embodiments, third lateral widths W_{S2_EXT}-RA, W_{S2_EXT}-RB, and W_{S2_EXT}-RC of extended portions of second spectral filters 344 are the same. In some embodiments, paired PDAF pixel cells (e.g., a first pair including 520-PDAF-LA and 520-PDAF-RA, a second pair including 520-PDAF-LB and 520-PDAF-RB, and/or a third pair including 520-PDAF-LC and 520-PDAF-RC) have third lateral widths of extended portions of second spectral filters 344 that are the same.

In some embodiments, each individual pair of PDAF pixel cells (e.g., the first pair including 520-PDAF-LA and 520-PDAF-RA, the second pair including 520-PDAF-LB and 520-PDAF-RB, and/or the third pair including 520-PDAF-LC and 520-PDAF-RC) are each individually arranged to be laterally surrounded by imaging pixel cells (e.g., QPD pixel cells 310 illustrated in FIG. 4B-4D, which may correspond to plurality of QPD pixel cells 210 illustrated in FIG. 2A-2B). Groups of pixels or photodiodes included in QPD pixel cells 310 surrounding the first pair, second pair, and/or third pair of PDAF pixel cells may be classified as first level pixels (e.g., first level pixels 230 illustrated in FIG. 2A-2B), corner pixels (e.g., corner pixels 240 illustrated in FIG. 2A-2B), second level pixels (e.g., second level pixels 250 illustrated in FIG. 2A-2B), or third level pixels (e.g., third level pixels 260 illustrated in FIG. 2A-2B).

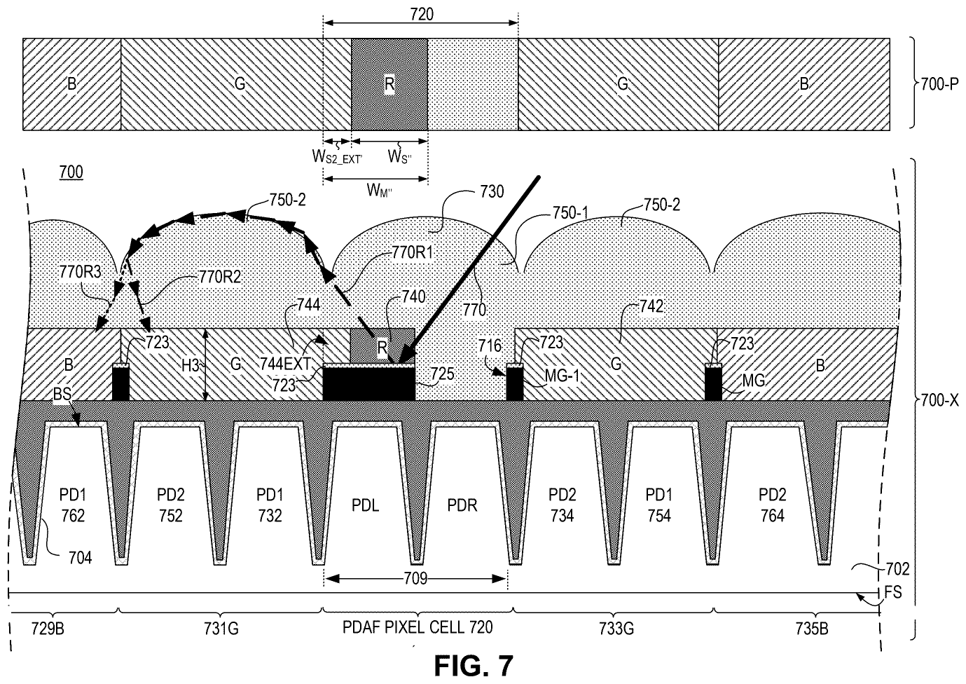

FIG. 7 illustrates a cross-sectional view 700-X and a plan view 700-P of a partial pixel cell array of an image sensor including a PDAF pixel cell 720 with a combination of a spectral filter and an antireflection layer for reduced induced crosstalk, in accordance with teachings of the disclosure. PDAF pixel cell 720 represents an improved phase detection structure relative to PDAF pixel cell 220 illustrated in FIG. 2A-2B. In the illustrated embodiment, PDAF pixel cell 720 includes a plurality of photodiodes, including left photodiodes PDL and right photodiodes PDR (e.g., first, second, third, and forth photodiodes arranged in a two-by-two array) surrounded by imaging pixels (e.g., pixel cell 729B including photodiode PD1 762, pixel cell 731G including photodiode PD2 752 and PD1 732, pixel cell 733G including photodiode PD2 734 and PD1 754, and pixel cell 735B including photodiode 764) formed within semiconductor material 702. PDAF pixel cell 720 further includes metal shield 725, spectral filter 740, extended portion 744EXT of second spectral filter 744, antireflection layer 723, and microlens 750-1. In the illustrated embodiment, antireflection layer 723 is disposed between spectral filter 740 and metal shield 725. In the same embodiment, antireflection layer 723 is disposed between extended portion 744EXT of second spectral filter 744 and metal shield 725.

PDAF pixel cell 720 includes a photosensitive region 709 (e.g., defined by isolation structure 704) formed in semiconductor material 702 corresponding to regions where left photodiodes PDL and right photodiodes PDR are located (e.g., doped regions of semiconductor material 702 that collectively form left photodiodes PDL and right photodiodes PDR). Semiconductor material 702 includes front side surface FS and the backside surface BS opposite of the front side FS. Metal shield 725 is disposed between microlens 750-1 and photosensitive region 709 (e.g., to block incident light from reaching left photodiodes PDL or right photodiodes PDR depending on an orientation of PDAF pixel cell 720). In the illustrated embodiment, pixel cell array 700 includes isolation structure 704 (e.g., a plurality of deep trench isolation structures) formed in semiconductors material 702 to provide isolation between individual photodiodes (e.g., left photodiodes PDL and right photodiodes PDR may be isolation from each other via isolation structure 704) included in phase detection autofocus pixel cells and normal imaging pixel cells (e.g., pixel cells 729B, 731G, 733G, 735G, and so on). In some embodiments, a metal grid 716 is formed between individual color filters (“R”, “G”, or “B”) of the color filter array. In the same or other embodiments, metal grid 716 may be vertically aligned with isolation structure 704 to form a plurality of apertures defining light exposure or sensing regions of individual pixels or pixel cells included in pixel cell array 700. Apertures formed by metal grid 716 may be filled with individual color filters such that a given pixel or pixel cell is associated with a predetermined color (e.g., red, green, or blue). Metal grid 716 includes a plurality metal grid segments MG separating each individual color filter. QPD pixel cell 731G includes second spectral filter 744 (e.g., a green color filter) with microlens 750-2 optically aligned with underlying photodiodes (i.e., a two-by-two array of photodiodes including PD1 732 and PD2 752). QPD pixel cell 733G includes another spectral filter 742 (e.g., a green color filter) with a corresponding microlens optically aligned with underlying photodiodes (i.e., a two-by-two array of photodiodes including PD1 754 and PD2 734).

PDAF pixel cell 720 includes many similar features as PDAF pixel cell 520 illustrated in FIG. 5 and PDAF pixel cell 320 illustrated in FIG. 3 and thus may include like-labeled elements (e.g., semiconductor material 702 may correspond to semiconductor material 502, isolation structure 704 may correspond to isolation structure 504, microlens 750-1 may correspond to microlens 550-1, and so on) and thus may have the same or similar features. One difference is spectral filter 540 is antireflection layer 723 is formed over metal grid segments MG-1, MG, and metal shield 725 to further reduce crosstalk induced by metal shield 725 and/or metal grid segments included in metal grid 716.

In the illustrated embodiment, antireflection layer 723 is disposed between microlens 750-1 and metal shield 725. Antireflection layer 723 is further disposed between spectral filter 740 and metal shield 725 for reducing and/or attenuating reflection from metal shield 725 (e.g., reduce intensity or strength of reflected light 770R1 and subsequently reflected light 770R2 and 770R3). In some embodiments, spectral filter 740 is configured to pass a light wavelength range that differs from or is outside of a transmission range of an adjacent color filter (e.g., second spectral filter 740 of adjacent QPD pixel cell 731G and/or spectral filter 742 of adjacent QPD pixel cell 733G).

In some embodiments, spectral filter 740 is a non-green color filter. In the same or different embodiments, spectral filter 740 may be configured to block light having a wavelength in a range from 500 nm to 550 nm. In some embodiments, spectral filter 740 may be a red color filter or a spectral filter that allows light with a wavelength range from 600 nm to 750 nm to propagate). In the same or different embodiments, red color filter material for forming spectral filter 740 is formed of a photo-resistive material or a resin material containing red color agent such as red pigment or red dye) that transmits or passes red light (e.g., light having a wavelength ranging from 600 nm to 750 nm) while reflecting and/or absorbing other colors of light.

In some embodiments, spectral filter 740 may be a blue color filter or a spectral filter that allows light with a wavelength range from 400 nm to 450 nm). Thus in some embodiments, the spectral filter 740 may be formed of a blue color filter material. In one example, the blue color filter material is formed of a photo-resistive material or a resin material containing a blue color agent such as blue pigment or blue dye) that transmits or passes blue light (e.g., light having a wavelength ranging from 400 nm to 450 nm) while reflecting and/or absorbing other colors of light.

In some embodiments, antireflection layer 723 is formed of titanium nitride (TiN) having a thickness ranging from 500 angstroms to 1000 angstroms. It is appreciated in other embodiments, antireflection layer 723 may be formed of other suitable materials such as titanium (Ti), a combination of titanium nitride and titanium, tungsten, or combinations thereof with appropriate thickness.

In operation, light 770 reflected by the metal shield 725 (e.g., reflected light ray 770R1 directed by microlens 550-1) is first attenuated or reduced, for example, by antireflective layer 723 and then filtered by spectral filter 740 before propagating to an adjacent QPD pixel (e.g., pixel associated with PD1 732 included in QPD pixel cell 731G). Spectral filter 740 is configured to filter portions of light included in reflected light ray 770R1 that is not filtered by the spectral filter (e.g., second spectral filter 744) of the adjacent QPD pixel. As such, crosstalk for second level pixels (e.g., pixels associated with photodiode 752 PD2 of QPD pixel cell 731G) and third level pixels (e.g., photodiode 762 PD1 of QPD pixel cell 729B) from reflected light (e.g., reflected light ray 770R2 and/or 770R3) may be reduced or minimized to improve PD induced crosstalk (e.g., due to PDAF pixel cell 720).

In some embodiments, second spectral filter 744 of the adjacent QPD pixel cell 731G may optionally have an extended portion 744EXT that extends into a pixel region of PDAF pixel cell 720 in a similar manner to PDAF pixel cell 520 illustrated in FIG. 5. In such an embodiment, extended portion 744EXT is disposed between microlens material 730 and antireflection layer 723. In some embodiments, extended portion 744EXT has a lateral width W_{S2_EXT′} along a direction that is parallel to a backside surface BS of semiconductor material 702. In some embodiments, a ratio of lateral width W_{S2_EXT′} of extended portion 744EXT to lateral width W_{M″} of metal shield 725 may range from 0 to 0.4. In some embodiments, a combined lateral width of extended portion 744EXT and the spectral filter 740 may be substantially (e.g., within manufacturing tolerances such as 10% the same as lateral width W_{M″} of metal shield 725.

In some embodiments, antireflection layer 723 may optionally also be formed on or otherwise disposed on metal grid segments included in a metal grid 716. In some embodiments, metal grid 716 and metal shield 725 may be formed during a same process.

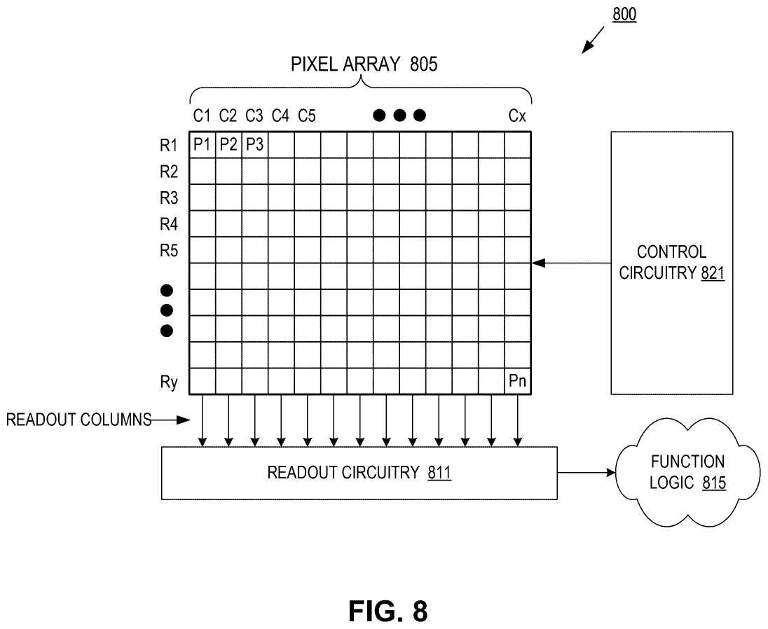

FIG. 8 illustrates a block diagram of an imaging system 800 for an image sensor, in accordance with teachings of the disclosure. Imaging system 800 includes pixel cell array 805, control circuitry 821, readout circuitry 811, and function logic 815. In one embodiment, pixel cell array 805 is a two-dimensional (2D) array of QPD pixel cells (e.g., pixel cells P1, P2 . . . , Pn) including imaging pixel cells and sparsely distributed PDAF pixel cells as illustrated in embodiments of the disclosure. As illustrated, pixel cells are arranged into rows (e.g., rows R1 to Ry) and columns (e.g., column C1 to Cx) to acquire image data of a person, place, object, etc., which can then be used to render an image or video of the person, place, object, etc. However, photodiodes, pixels, and/or pixel cells of imaging system 800 do not have to be arranged into rows and columns and may take other configurations.

In the various examples, readout circuitry 811 may be configured to read out the image signals at different conversion gains through column bitlines. In various examples, readout circuitry 811 may include current sources, routing circuitry, and comparators that may be included in analog to digital converters or otherwise.

In one embodiment, after each photodiode/pixel in pixel cell array 805 has acquired its image data or image charge, the image data is readout by readout circuitry 811 and then transferred to function logic 815. In various examples, readout circuitry 811 may include amplification circuitry, analog-to-digital (ADC) conversion circuitry, or otherwise. Function logic 815 may simply store the image data or even manipulate the image data by applying post image effects (e.g., autofocus based on phase detection signal provided by PDAF pixel cells, crop, rotate, remove red eye, adjust brightness, adjust contrast, or otherwise). In the same or another embodiment, readout circuitry 811 may readout a row of image data at a time along readout column lines (illustrated) or may readout the image data using a variety of other techniques (not illustrated), such as a serial readout or a full parallel readout of all pixels simultaneously. In one embodiment, control circuitry 821 is coupled to pixel cell array 805 to control operation pixel cell array 805. For example, control circuitry 821 may generate a shutter signal for controlling image acquisition. In some embodiments, control circuitry 821 may be configured to generate drive signals (e.g., transfer signals, reset signals, and row-select signals) for controlling operation of pixel circuitries associated with pixel cell array 805.

It is appreciated that imaging system 800 may be included in an image sensor that can be incorporated into digital camera, cell phone, laptop computer, automobile, surveillance camera or the like. Additionally, imaging system 800 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 800, extract image data from imaging system 800, or manipulate image data supplied by imaging system 800.

It is appreciated that embodiments of the disclosure illustrated in FIG. 1-8 may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. A phase detection autofocus (PDAF) pixel cell, comprising:
a photosensitive region including one or more photodiodes formed within a semiconductor material proximate to a backside surface of the semiconductor material;
a microlens optically aligned with the photosensitive region;
a metal shield disposed between the microlens and the photosensitive region; and
a spectral filter disposed between the microlens and the metal shield, wherein a first lateral width of the spectral filter is less than a second lateral width of the metal shield along a direction parallel to the backside surface to form a gap extending from an edge of the spectral filter toward an edge of the metal shield when viewed from a plan view.

2. The PDAF pixel cell of claim 1, wherein the metal shield partially covers the photosensitive region, and wherein the spectral filter partially covers the metal shield.

3. The PDAF pixel cell of claim 2, wherein partial coverage of the photosensitive region provided by the metal shield defines an uncovered portion of the photosensitive region, and wherein the spectral filter does not extend over the uncovered portion of the photosensitive region.

4. The PDAF pixel cell of claim 1, wherein a third lateral width of the gap along the direction parallel to the backside surface is less than the first lateral width of the spectral filter.

5. The PDAF pixel cell of claim 1, wherein the edge of the metal shield corresponds to an inner edge of the metal shield disposed closer to a midpoint of the photosensitive region relative to an outer edge of the metal shield, wherein the inner edge is opposite the outer edge.

6. The PDAF pixel cell of claim 5, wherein the gap is filled by microlens material included in the microlens.

7. The PDAF pixel cell of claim 1, wherein the edge of the metal shield corresponds to an outer edge of the metal shield, wherein the metal shield further includes an inner edge opposite the outer edge, and wherein the inner edge of the metal shield is disposed closer to a midpoint of the photosensitive region relative to the outer edge.

8. The PDAF pixel cell of claim 1, further comprising a second spectral filter disposed between the metal shield and the microlens adjacent to the spectral filter, wherein a first photoresponse of the spectral filter is different from a second photoresponse of the second spectral filter, and wherein the gap is filled by the second spectral filter.

9. The PDAF pixel cell of claim 8, wherein the spectral filter corresponds to a red color filter, and wherein the second spectral filter corresponds to a green color filter or a blue color filter.

10. The PDAF pixel cell of claim 8, wherein a corresponding lateral width of the second spectral filter disposed over the metal shield along the direction parallel to the backside surface is less than the first lateral width of the spectral filter.

11. The PDAF pixel cell of claim 1, further comprising an antireflection layer disposed between the spectral filter and the metal shield.

12. The PDAF pixel cell of claim 1, wherein a vertical thickness of the spectral filter along a direction normal to the backside surface is substantially uniform throughout the first lateral width of the spectral filter.

13. An image sensor, comprising:
a pixel cell array including a plurality of pixel cells arranged in rows and columns, wherein the plurality of pixel cells includes phase detection autofocus (PDAF) pixel cells and imaging pixel cells laterally surrounding individual PDAF pixel cells included in the plurality of PDAF pixel cells, wherein the individual PDAF pixel cells each includes:
a photosensitive region including one or more photodiodes formed within a semiconductor material proximate to a backside surface of the semiconductor material;
a microlens optically aligned with the photosensitive region;
a metal shield disposed between the microlens and the photosensitive region, wherein the metal shield partially covers the photosensitive region to define an uncovered portion of the photosensitive region; and
a spectral filter disposed between the microlens and the metal shield, wherein the spectral filter partially covers the metal shield to define an uncovered portion of the metal shield.

14. The image sensor of claim 13, wherein a lateral width of the metal shield for each of the plurality of PDAF pixel cells varies based on a position of the individual PDAF pixel cells within the image sensor.

15. The image sensor of claim 13, wherein the PDAF pixel cells include a first PDAF pixel cell associated with a first chief ray angle and a second PDAF pixel cell associated with a second chief ray angle different from the first chief ray angle, wherein the first PDAF pixel cell and the second PDAF pixel cell have a same orientation, and wherein a lateral width of the spectral filter for first PDAF pixel cell is greater than a lateral width of the spectral filter for the second PDAF pixel cell.

16. The image sensor of claim 13, wherein individual imaging pixel cells included in the imaging pixel cells laterally surrounding the individual PDAF pixel cells each include corresponding spectral filters disposed over respective photosensitive regions of the individual imaging pixel cells, and wherein a first photoresponse of the spectral filter included in the individual PDAF pixel cells is different than a second photoresponse of the corresponding spectral filters included in the individual imaging pixel cells.

17. The image sensor of claim 16, wherein individual PDAF pixel cells includes a first PDAF pixel row or column adjacent to a first imaging pixel cell included in the individual imaging pixel cells, wherein the second spectral filter included in the first imaging pixel cell extends over the uncovered portion of the metal shield included in the first PDAF pixel cell such that the second spectral filter is disposed between the microlens of the first PDAF pixel cell and the metal shield of the first PDAF pixel cell.

18. The image sensor of claim 13, wherein for each of the individual PDAF pixel cells, microlens material included in the microlens fills gaps defined by the uncovered portion of the photosensitive region and the uncovered portion of the metal shield.

19. The image sensor of claim 13, wherein for each of the individual PDAF pixel cells, a first lateral width of the spectral filter is less than a second lateral width of the metal shield along a direction parallel to the backside surface to form a gap extending from an edge of the spectral filter toward an edge of the metal shield when viewed from a plan view.

20. The PDAF pixel cell of claim 19, wherein a third lateral width of the gap along the direction parallel to the backside surface for each of the individual PDAF pixel cells is substantially equal.
